(19) United States
(12) Patent Application Publication
(10) Pub. No.: US 2026/0213709 A1
(43) Pub. Date: Jul. 23, 2026

(54) CIRCUIT DEVICE AND OSCILLATOR

(71) Applicant: SEIKO EPSON CORPORATION, Tokyo (JP)

(72) Inventor: Wataru Okumura, Minamiminowa-mura (JP)

(21) Appl. No.: 19/453,135

(22) Filed: Jan. 20, 2026

(30) Foreign Application Priority Data
Jan. 21, 2025 (JP) 2025-008211

(51) Int. Cl. H03B 5/04; H03B 5/24; H03B 5/36

(52) U.S. Cl. CPC H03B 5/04; H03B 5/24; H03B 5/364; H03B 2201/0208

(57) ABSTRACT

A circuit device includes an oscillation circuit configured to cause a resonator to oscillate and generate an oscillation signal, a temperature compensation circuit including an operational amplifier and configured to output a temperature compensation voltage for an oscillation frequency of the oscillation signal to the oscillation circuit based on a temperature detection voltage from a temperature detection circuit, and a reference voltage generation circuit for temperature compensation configured to generate a reference voltage for temperature compensation and output the reference voltage to the temperature compensation circuit. The input limit voltage of the first input terminal of the operational amplifier has the temperature characteristic of the first polarity that is one of positive and negative, and the reference voltage input to the first input terminal of the operational amplifier has the temperature characteristic of the first polarity that is the same as the polarity of the temperature characteristic of the input limit voltage.

The present application is based on, and claims priority from JP Application Serial Number 2025-008211, filed Jan. 21, 2025, the disclosure of which is hereby incorporated by reference herein in its entirety.

### BACKGROUND

### 1. Technical Field

The present disclosure relates to a circuit device and an oscillator.

### 2. Related Art

In a circuit device that causes a resonator such as a quartz crystal resonator to oscillate, temperature compensation of an oscillation frequency is performed. For example, JP-A-2023-90099 discloses a circuit device that performs such a temperature compensation. In this circuit device, for example, temperature compensation of the oscillation frequency of the resonator, which varies with a temperature change, is performed by controlling capacitance of a variable capacitance circuit of an oscillation circuit based on a temperature compensation voltage.

However, it is found that there is a problem in that it is difficult to secure an output voltage range of the temperature compensation voltage along with reduction in a power supply voltage or the like.

### SUMMARY

According to an aspect of the present disclosure, there is provided a circuit device including an oscillation circuit configured to cause a resonator to oscillate and generate an oscillation signal, a temperature compensation circuit including an operational amplifier and configured to output a temperature compensation voltage for an oscillation frequency of the oscillation signal to the oscillation circuit based on a temperature detection voltage from a temperature detection circuit, and a reference voltage generation circuit for temperature compensation configured to generate a reference voltage for temperature compensation and output the reference voltage for temperature compensation to the temperature compensation circuit, in which an input limit voltage of a first input terminal of the operational amplifier has a temperature characteristic of a first polarity that is one of positive and negative, and the reference voltage input to the first input terminal of the operational amplifier has a temperature characteristic of the first polarity that is the same as the polarity of the temperature characteristic of the input limit voltage.

According to another aspect of the present disclosure, there is provided an oscillator including the circuit device according to the above aspect, and the resonator.

### BRIEF DESCRIPTION OF THE DRAWINGS

FIG. 1 is a configuration example of a circuit device according to the present embodiment.

FIG. 2 is a detailed configuration example of the circuit device and an oscillator according to the present embodiment.

FIG. 3 is a configuration example of a temperature compensation circuit.

FIG. 4 is an explanatory diagram of temperature compensation processing.

FIG. 5 is a configuration example of an oscillation circuit.

FIG. 6 is a configuration example of a function current generation circuit.

FIG. 7 is an explanatory diagram of a method of generating a temperature compensation current.

FIG. 8 is a configuration example of an inverting amplifier circuit.

FIG. 9 is a configuration example of an operational amplifier.

FIG. 10 is an explanatory diagram of a temperature characteristic of a temperature compensation voltage.

FIG. 11 is an explanatory diagram of an amplifier circuit of current-voltage conversion.

FIG. 12 is a temperature characteristic example for describing a method of a comparative example.

FIG. 13 is a temperature characteristic example for describing a method of the present embodiment.

FIG. 14 is another configuration example of the operational amplifier.

FIG. 15 is a temperature characteristic example of a method of a comparative example.

FIG. 16 is a temperature characteristic example for describing a method of the present embodiment.

FIG. 17 is a configuration example of a reference voltage generation circuit.

FIG. 18 is a configuration example of a reference circuit.

FIG. 19 is another configuration example of the reference circuit.

FIG. 20 is still another configuration example of the reference circuit.

FIG. 21 is a configuration example of a regulator.

### DESCRIPTION OF EMBODIMENTS

In the following, the present embodiment will be described. The present embodiment to be described below does not unreasonably limit the contents described in the claims. In addition, not all configurations described in the present embodiment are essential configuration requirements.

### 1. Circuit Device

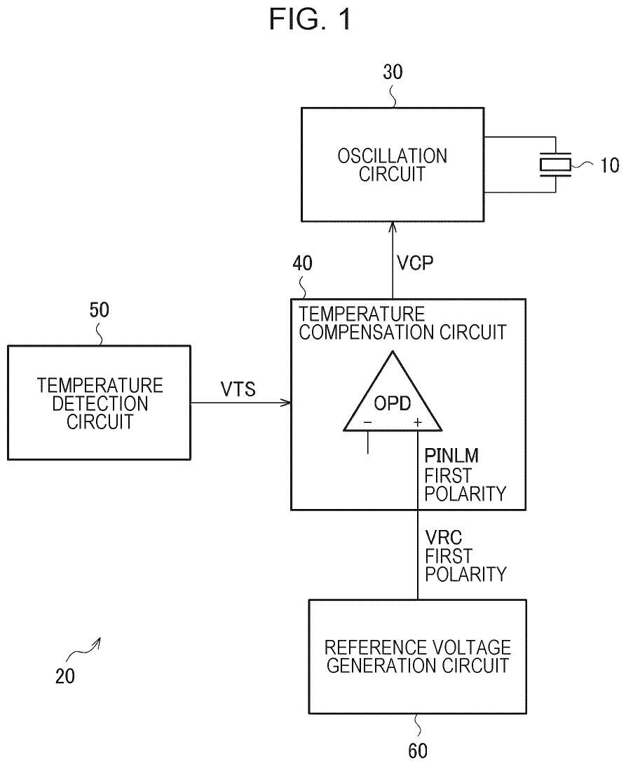

FIG. 1 shows a configuration example of a circuit device 20 according to the present embodiment. The circuit device 20 of the present embodiment includes an oscillation circuit 30, a temperature compensation circuit 40, and a reference voltage generation circuit 60. In addition, the circuit device 20 may include a temperature detection circuit 50. In addition, the resonator 10 is electrically coupled to the circuit device 20, and for example, an oscillator is configured by the resonator 10 and the circuit device 20. The configuration of the circuit device 20 is not limited to the configuration of FIG. 1, and various modifications such as omitting some of the components, adding other components, and replacing some of the components with other components can be implemented.

The resonator 10 is an element that generates mechanical resonance by an electrical signal. The resonator 10 can be realized by a resonator element such as a quartz crystal resonator element. For example, the resonator 10 can be realized by a quartz crystal resonator element having a cut angle that thickness-shear resonates, such as an AT cut or an SC cut, a tuning fork type quartz crystal resonator element, a double tuning fork type quartz crystal resonator element, or the like. For example, the resonator 10 may be a resonator built in a temperature compensated crystal oscillator (TCXO) that does not include a constant temperature bath, or may be a resonator built in an oven controlled crystal oscillator (OCXO) that includes a constant temperature bath. The resonator 10 of the present embodiment can also be realized by various resonator elements such as a resonator element other than a thickness-shear resonance type, a tuning fork type, a double tuning fork type, or a piezoelectric resonator element formed of a material other than quartz crystal. For example, as the resonator 10, a surface acoustic wave (SAW) resonator, a micro electro mechanical systems (MEMS) resonator as a silicon resonator formed by using a silicon substrate, or the like can be adopted.

The circuit device 20 is an integrated circuit device called an integrated circuit (IC). For example, the circuit device 20 is an IC manufactured by a semiconductor process, and is a semiconductor chip in which a circuit element is formed above a semiconductor substrate. The circuit device 20 operates based on a power supply voltage supplied from the outside.

The oscillation circuit 30 is a circuit that causes the resonator 10 to oscillate. For example, the oscillation circuit 30 generates an oscillation signal by oscillating the resonator 10. For example, the oscillation signal is an oscillation clock signal. For example, the oscillation circuit 30 can be realized by a drive circuit for oscillation that is electrically coupled to one end and the other end of the resonator 10, and a passive element such as a capacitor and a resistor. For example, the drive circuit can be realized by a CMOS inverter circuit or a bipolar transistor. The drive circuit is a core circuit of the oscillation circuit 30, and the drive circuit causes the resonator 10 to oscillate by voltage-driving or current-driving the resonator 10. As the oscillation circuit 30, various types of oscillation circuits such as an inverter type, a Pierce type, a Colpitts type, and a Hartley type can be used. It should be noted that coupling in the present embodiment is electrical coupling. The electrical coupling is coupling in which electrical signals are coupled so as to be transmittable, and is coupling that enables transmission of information by electrical signals. The electrical coupling may be coupling via the passive element or the like.

The temperature detection circuit 50 is a sensor circuit that detects a temperature. Specifically, the temperature detection circuit 50 outputs a temperature-dependent voltage that changes according to the ambient temperature as a temperature detection voltage VTS. For example, the temperature detection circuit 50 generates a temperature detection voltage VTS, which is a temperature detection signal, by using a circuit element having temperature dependency. Specifically, the temperature detection circuit 50 outputs a temperature detection voltage VTS whose voltage changes depending on the temperature by using, for example, temperature dependency of a forward voltage of a PN junction. A modification in which a digital type temperature detection circuit is used as the temperature detection circuit 50 is also possible. In this case, the temperature detection voltage VTS may be generated by performing D/A conversion on temperature detection data.

The temperature compensation circuit 40 performs temperature compensation of the oscillation frequency of the oscillation circuit 30. For example, the temperature compensation circuit 40 outputs a temperature compensation voltage VCP of the oscillation frequency of the oscillation signal to the oscillation circuit 30 based on the temperature detection voltage VTS from the temperature detection circuit 50. The temperature compensation is processing of suppressing and compensating for fluctuations of the oscillation frequency due to the temperature fluctuations, for example. That is, the temperature compensation circuit 40 performs the temperature compensation of the oscillation frequency of the oscillation circuit 30 such that the oscillation frequency is constant even when the temperature fluctuates. It is also possible to perform a modification in which the oscillation frequency is digitally adjusted in a variable capacitance circuit of the oscillation circuit 30 by using temperature compensation data obtained by A/D converting the temperature compensation voltage VCP.

The temperature compensation circuit 40 includes an operational amplifier OPD and outputs the temperature compensation voltage VCP by using the operational amplifier OPD. For example, as will be described later, the temperature compensation circuit 40 includes a current-voltage conversion circuit that converts the temperature compensation current into the temperature compensation voltage VCP, and the operational amplifier OPD provided in the current-voltage conversion circuit outputs the temperature compensation voltage VCP.

The reference voltage generation circuit 60 for temperature compensation generates a reference voltage VRC for temperature compensation. The generated reference voltage VRC is output to the temperature compensation circuit 40. The temperature compensation circuit 40 generates a temperature compensation voltage VCP by performing the temperature compensation based on the reference voltage VRC. For example, the temperature compensation voltage VCP is set to be the reference voltage VRC at a temperature of an inflection point of the temperature compensation voltage VCP. The temperature compensation voltage VCP changes with reference to the reference voltage VRC, for example, changes to a positive side with respect to the reference voltage VRC or changes to a negative side with respect to the reference voltage VRC. The temperature of the inflection point is, for example, a typical temperature, and is, for example, −25° C. For example, a higher-order temperature compensation current generated by the temperature compensation circuit 40 is set to be, for example, 0 at the temperature of the inflection point.

Then, in the present embodiment, an input limit voltage PINLM of a first input terminal of the operational amplifier OPD included in the temperature compensation circuit 40 has a temperature characteristic of a first polarity that is one of positive and negative. In FIG. 1, the first input terminal of the operational amplifier OPD is, for example, a non-inverting input terminal, and the input limit voltage PINLM of the non-inverting input terminal has the temperature characteristic of the first polarity. In this case, an input limit voltage of an inverting input terminal, which is a second input terminal of the operational amplifier OPD, may also have the temperature characteristic of the first polarity. The input limit voltage is an input lower limit voltage or an input upper limit voltage. The reference voltage VRC input to the first input terminal of the operational amplifier OPD also has the temperature characteristic of the first polarity, which is the same as the polarity of the temperature characteristic of the input limit voltage PINLM. That is, when the input limit voltage PINLM of the first input terminal of the operational amplifier OPD of the temperature compensation circuit 40 has the temperature characteristic of the first polarity that is one of positive and negative, the reference voltage generation circuit 60 outputs the reference voltage VRC having the temperature characteristic of the first polarity which is the same as the input limit voltage PINLM to the first input terminal of the operational amplifier OPD.

For example, the reference voltage VRC input to the first input terminal of the operational amplifier OPD is input to transistors of a differential pair of the operational amplifier OPD. When the transistors of the differential pair are bipolar transistors, the reference voltage VRC is input to bases of the bipolar transistors. When the transistors of the differential pair are MOS transistors, the reference voltage VRC is input to gates of the MOS transistors. Therefore, the input limit voltage PINLM of the first input terminal of the operational amplifier OPD has the temperature characteristic of the first polarity that is one of positive and negative. For example, when the transistors of the differential pair are npn bipolar transistors or N-type MOS transistors, an input lower limit voltage, which is the input limit voltage PINLM, has, for example, a negative temperature characteristic. In addition, when the transistors of the differential pair are pnp bipolar transistors or P-type MOS transistors, an input upper limit voltage, which is the input limit voltage PINLM, has, for example, a positive temperature characteristic.

Therefore, when the reference voltage VRC having a constant voltage with respect to the temperature change is input to the first input terminal of the operational amplifier OPD, an output voltage range of the operational amplifier OPD becomes narrow when the power supply voltage of the circuit device 20 is lowered. Therefore, when the power supply voltage is lowered, the voltage range of the temperature compensation voltage VCP output by the operational amplifier OPD of the temperature compensation circuit 40 is narrowed, and it becomes difficult to perform appropriate temperature compensation.

In this regard, in the present embodiment, the temperature characteristic of the input limit voltage PINLM of the first input terminal of the operational amplifier OPD and the temperature characteristic of the reference voltage VRC are in the same first polarity. For example, it is assumed that the transistors of the differential pair are npn bipolar transistors or N-type MOS transistors, and that the input lower limit voltage, which is the input limit voltage PINLM, has a negative temperature characteristic. In this case, the reference voltage generation circuit 60 outputs the reference voltage VRC having a negative temperature characteristic that is the same as a polarity of the temperature characteristic of the input lower limit voltage. In addition, it is assumed that the transistors of the differential pair are pnp bipolar transistors or P-type MOS transistors, and that the input upper limit voltage, which is the input limit voltage PINLM, has a positive temperature characteristic. In this case, the reference voltage generation circuit 60 outputs the reference voltage VRC having a positive temperature characteristic that is the same as a polarity of the temperature characteristic of the input upper limit voltage. In this manner, when the input limit voltage PINLM decreases with the temperature change, the reference voltage VRC also decreases, and when the input limit voltage PINLM increases with the temperature change, the reference voltage VRC also increases. Thus, the input limit voltage PINLM and the reference voltage VRC change with the temperature characteristic having the same polarity with respect to the temperature change. Therefore, even when the power supply voltage of the circuit device 20 is lowered, it is possible to suppress the output voltage range of the operational amplifier OPD of the temperature compensation circuit 40 from becoming narrow, and it is possible to output the temperature compensation voltage VCP in a wider voltage range. Therefore, it is possible to realize appropriate temperature compensation.

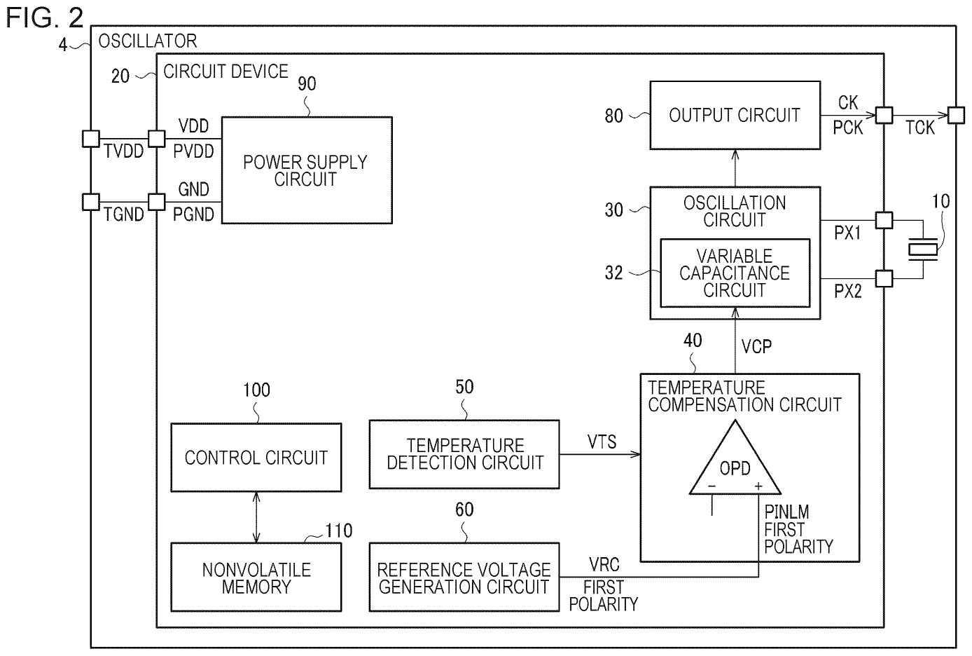

FIG. 2 shows a detailed configuration example of the circuit device 20 and an oscillator 4 according to the present embodiment. In FIG. 2, the circuit device 20 includes the temperature detection circuit 50, an output circuit 80, a power supply circuit 90, a control circuit 100, and a nonvolatile memory 110 in addition to the oscillation circuit 30, the temperature compensation circuit 40, and the reference voltage generation circuit 60. In addition, the oscillator 4 includes the resonator 10 and the circuit device 20, and the resonator 10 is electrically coupled to the circuit device 20. For example, the resonator 10 and the circuit device 20 are electrically coupled to each other by using internal wiring of a package that accommodates the resonator 10 and the circuit device 20, a bonding wire, a metal bump, or the like. The configurations of the circuit device 20 and the oscillator 4 are not limited to the configuration of FIG. 2, and various modifications can be made such as omitting some of the components, adding other components, and replacing some of the components with other components.

The circuit device 20 further includes pads PVDD, PGND, PX1, PX2, and PCK. The pads are terminals of the circuit device 20, which is a semiconductor chip. For example, in a pad region, a metal layer is exposed from a passivation film, which is an insulating layer, and the pad, which is the terminal of the circuit device 20, is configured by the exposed metal layer. The pads PVDD and PGND are a power supply pad and a ground pad, respectively. The power supply voltage VDD from an external power supply device is supplied to the pad PVDD. The pad PGND is a pad to which GND, which is the ground voltage, is supplied. For example, the ground voltage is a ground potential. In the present embodiment, GND is referred to as VSS as appropriate. For example, VDD corresponds to a high potential side power supply, and VSS, which is GND, corresponds to a low potential side power supply. The pads PX1 and PX2 are pads for coupling of the resonator 10. The pad PCK is a pad for outputting a clock signal CK. The pads PVDD, PGND, and PCK are electrically coupled to terminals TVDD, TGND, and TCK, which are external terminals for external coupling of the oscillator 4, respectively. For example, each of these pads and each of the terminals are electrically coupled by using internal wiring of the package, bonding wires, metal bumps, or the like. A terminal and a pad to which a control voltage from the outside is input may be provided so that an external system can control an oscillation frequency by the control voltage.

The oscillation circuit 30 is electrically coupled to the resonator 10 via the pads PX1 and PX2. The pads PX1 and PX2 are pads for coupling of the resonator. The drive circuit for oscillation of the oscillation circuit 30 is provided between the pad PX1 and the pad PX2. The oscillation circuit 30 includes a variable capacitance circuit 32. For example, the variable capacitance circuit 32 is a circuit that changes capacitance of at least one of the one end and the other end of the resonator 10, and the oscillation frequency of the oscillation circuit 30 can be adjusted by adjusting the capacitance of the variable capacitance circuit 32. That is, the variable capacitance circuit 32 is electrically coupled to at least one of the pads PX1 and PX2, so that load capacitance of the oscillation circuit 30 can be variably adjusted. The variable capacitance circuit 32 can be realized by, for example, a variable capacitance element such as a varactor. For example, the variable capacitance circuit 32 is configured by at least one variable capacitance element.

The temperature compensation circuit 40 performs analog temperature compensation by using, for example, polynomial approximation. For example, when the temperature compensation voltage VCP for compensating a frequency-temperature characteristic of the resonator 10 is approximated by a polynomial, the temperature compensation circuit 40 performs analog temperature compensation based on coefficient information of the polynomial. The analog temperature compensation is temperature compensation that is realized by, for example, addition processing of a current signal or a voltage signal, which is an analog signal. For example, when the temperature compensation voltage VCP is approximated by a higher-order polynomial, the zeroth-order coefficient, the first-order coefficient, and the higher-order coefficient of the polynomial are stored in a storage portion realized by, for example, the nonvolatile memory 110 or the like as zeroth-order correction data, first-order correction data, and higher-order correction data, respectively. The higher-order coefficient is, for example, a coefficient of a higher order than the first order, and the higher-order correction data is correction data corresponding to the higher-order coefficient. For example, when the temperature compensation voltage VCP is approximated by a third-order polynomial, a zeroth-order coefficient, a first-order coefficient, a second-order coefficient, and a third-order coefficient of the polynomial are stored in the storage portion as zeroth-order correction data, first-order correction data, second-order correction data, and third-order correction data. The temperature compensation circuit 40 performs temperature compensation based on the zeroth-order correction data to the third-order correction data. In this case, the second-order correction data and temperature compensation based on the second-order correction data may be omitted. In addition, for example, when the temperature compensation voltage VCP is approximated by a fifth-order polynomial, a zeroth-order coefficient, a first-order coefficient, a second-order coefficient, a third-order coefficient, a fourth-order coefficient, and a fifth-order coefficient of the polynomial are stored in the storage portion as zeroth-order correction data, first-order correction data, second-order correction data, third-order correction data, fourth-order correction data, and fifth-order correction data. The temperature compensation circuit 40 performs the temperature compensation based on the zeroth-order correction data to the fifth-order correction data. In this case, the second-order correction data or the fourth-order correction data, or the temperature compensation based on the second-order correction data or the fourth-order correction data may be omitted. The order of polynomial approximation may be optional, and, for example, polynomial approximation of an order higher than fifth order may be performed.

The power supply circuit 90 is supplied with, for example, a power supply voltage VDD or a ground voltage GND from the outside, and supplies various power supply voltages for internal circuits of the circuit device 20 to the internal circuits. For example, the power supply circuit 90 is supplied with the power supply voltage VDD from the pad PVDD and VSS, which is the ground voltage GND from the pad PGND, and supplies various power supply voltages for the internal circuits of the circuit device 20 to the internal circuits. For example, the power supply circuit 90 supplies a power supply voltage obtained by regulating a power supply voltage, or the like, to each circuit of the circuit device 20, such as the oscillation circuit 30, the temperature compensation circuit 40, and the temperature detection circuit 50.

The control circuit 100 is a circuit that performs various control processing, and is realized by, for example, a logic circuit or the like. For example, the control circuit 100 performs the overall control of the circuit device 20 or performs control of an operation sequence of the circuit device 20. The control circuit 100 performs various processing for controlling the oscillation circuit 30, performs control of the temperature compensation circuit 40, the temperature detection circuit 50, the reference voltage generation circuit 60, the output circuit 80, or the power supply circuit 90, or performs control of reading or writing of information of the nonvolatile memory 110. The control circuit 100 can be realized by, for example, a circuit of an application specific integrated circuit (ASIC) by automatic arrangement wiring such as a gate array.

The nonvolatile memory 110 is a memory that holds stored information even when power is not supplied. For example, the nonvolatile memory 110 is a memory that can hold information even when power is not supplied and can rewrite the information. The nonvolatile memory 110 stores various information necessary for the operation of the circuit device 20. The nonvolatile memory 110 can be realized by an electrically erasable programmable read-only memory (EEPROM) realized by a floating gate avalanche injection MOS memory (FAMOS memory) or a metal-oxide-nitride-oxide-silicon memory (MONOS memory), or the like. The nonvolatile memory 110 stores correction data such as first-order correction data and higher-order correction data used for temperature compensation of the temperature compensation circuit 40.

The output circuit 80 outputs a clock signal CK based on the oscillation signal of the oscillation circuit 30. For example, the output circuit 80 buffers the oscillation signal, which is an oscillation clock signal from the oscillation circuit 30 and outputs the oscillation signal to the pad PCK as the clock signal CK. The clock signal CK is output to the outside via a clock output terminal TCK of the oscillator 4. For example, the output circuit 80 outputs a clock signal CK in a single-ended CMOS signal format. The output circuit 80 may output a clock signal CK in a signal format other than CMOS. In addition, a clock signal generation circuit such as a PLL circuit that generates a clock signal CK having a frequency obtained by multiplying the frequency of the oscillation signal may be provided in the subsequent stage of the oscillation circuit 30, and the output circuit 80 may buffer and output the clock signal CK generated by the clock signal generation circuit.

The reference voltage generation circuit 60 for temperature compensation generates a reference voltage VRC for temperature compensation and outputs the reference voltage VRC to the temperature compensation circuit 40. For example, the reference voltage generation circuit 60 includes a reference circuit for generating a voltage VRF such as a BGR voltage. BGR is an abbreviation for bandgap reference. The reference voltage generation circuit 60 generates a reference voltage VRC based on the voltage VRF generated by the reference circuit. In this case, the reference voltage generation circuit 60 may have a regulator and generate a reference voltage VRC based on a voltage generated by the regulator based on the voltage VRF. For example, the regulator regulates the power supply voltage VDD based on the voltage VRF, and the reference voltage generation circuit 60 generates a reference voltage VRC based on the voltage generated by the regulator. For example, the reference voltage generation circuit 60 generates a reference voltage VRC by using, as a reference power supply voltage, the voltage VRF generated by the reference circuit or the voltage generated by the regulator based on the voltage VRF. For example, the reference voltage generation circuit 60 generates a reference voltage VRC by voltage-dividing the reference power supply voltage by a voltage generation circuit configured by a resistor circuit or the like. In this case, a plurality of reference voltages may be generated by changing a resistance division ratio in the voltage generation circuit and may be supplied to the temperature compensation circuit 40.

In the present application, the input limit voltage PINLM of the first input terminal of the operational amplifier OPD of the temperature compensation circuit 40 has the temperature characteristic of the first polarity, and the reference voltage VRC input to the first input terminal of the operational amplifier OPD also has the temperature characteristic of the first polarity. That is, the reference voltage generation circuit 60 generates a reference voltage VRC having a positive or negative temperature characteristic instead of the reference voltage VRC having a flat temperature characteristic, and outputs the reference voltage VRC to the temperature compensation circuit 40. In this case, at the temperature of the inflection point of the temperature compensation voltage VCP, the temperature compensation voltage VCP is the reference voltage VRC.

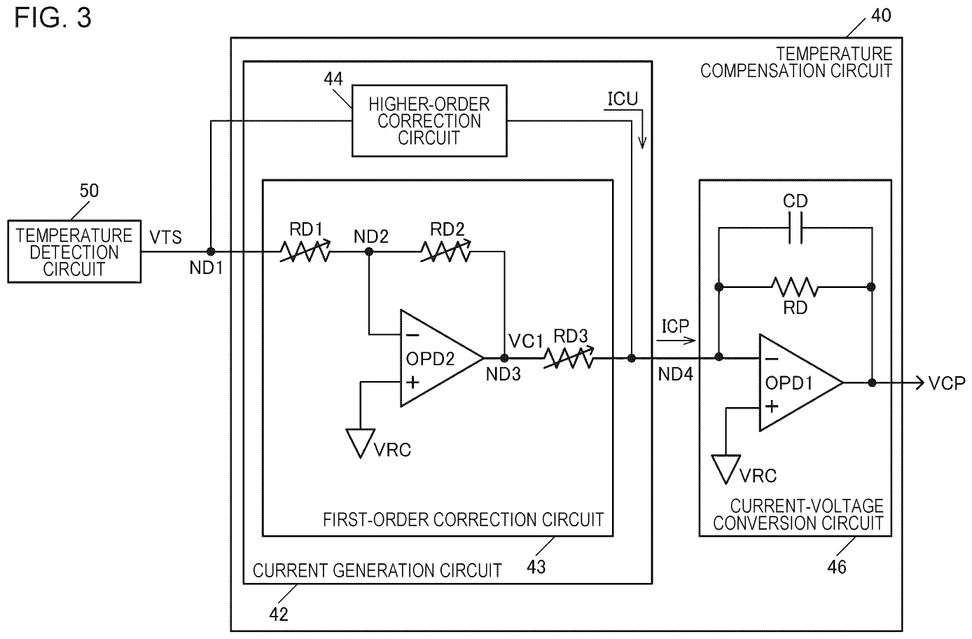

FIG. 3 shows a configuration example of the temperature compensation circuit 40. The configuration of the temperature compensation circuit 40 is not limited to the configuration of FIG. 3, and various modifications such as omitting some of the components, adding other components, and replacing some of the components with other components can be implemented.

The temperature compensation circuit 40 is a circuit that outputs the temperature compensation voltage VCP by polynomial approximation using the temperature as a variable. The temperature compensation circuit 40 includes a current generation circuit 42 and a current-voltage conversion circuit 46. The current generation circuit 42 generates a temperature compensation current ICP based on the temperature detection result of the temperature detection circuit 50. For example, the current generation circuit 42 generates a temperature compensation current ICP for temperature compensating the frequency-temperature characteristic of the resonator 10 based on the temperature detection voltage VTS which is the temperature detection result. The temperature compensation current ICP is also referred to as a function current. The current-voltage conversion circuit 46 converts the temperature compensation current ICP from the current generation circuit 42 into a voltage and outputs the temperature compensation voltage VCP. Specifically, the current-voltage conversion circuit 46 outputs the temperature compensation voltage VCP by using an operational amplifier OPD1.

The current generation circuit 42 includes a first-order correction circuit 43 and a higher-order correction circuit 44. The first-order correction circuit 43 and the higher-order correction circuit 44 are also referred to as a first-order compensation circuit and a higher-order compensation circuit. The first-order correction circuit 43 outputs a first-order current that approximates a first-order function based on the temperature detection voltage VTS. For example, the first-order correction circuit 43 outputs a first-order current based on the first-order correction data corresponding to a first-order coefficient of a polynomial in the polynomial approximation. The higher-order correction circuit 44 outputs, based on the temperature detection voltage VTS, a higher-order current ICU that approximates the higher-order function to the current-voltage conversion circuit 46. For example, the higher-order correction circuit 44 outputs a higher-order current ICU based on the higher-order correction data corresponding to the higher-order coefficient of the polynomial in the polynomial approximation. The current obtained by adding the higher-order current ICU and the first-order current obtained by the first-order correction circuit 43 is input to the current-voltage conversion circuit 46 as the temperature compensation current ICP.

As shown in FIG. 3, the first-order correction circuit 43 includes an operational amplifier OPD2 and resistors RD1 and RD2. In addition, the first-order correction circuit 43 can include a resistor RD3 having a variable resistance value. The operational amplifier OPD2 receives the reference voltage VRC at a non-inverting input terminal. The resistor RD1 is provided between an input node ND1 of the temperature detection voltage VTS and a node ND2 of the inverting input terminal of the operational amplifier OPD2. The resistor RD2 is provided between the node ND2 and a node ND3 of an output terminal of the operational amplifier OPD2. The resistor RD3 is provided between the node ND3 and an output node ND4 of the current generation circuit 42.

The current-voltage conversion circuit 46 outputs the temperature compensation voltage VCP by converting the temperature compensation current ICP, which is the sum of the first-order current and the higher-order current ICU, into a current voltage. Accordingly, the temperature compensation voltage VCP that approximates the polynomial function is generated. Specifically, the current-voltage conversion circuit 46 includes the operational amplifier OPD1 and a feedback resistor RD. The operational amplifier OPD1 receives the reference voltage VRC at the non-inverting input terminal, and the output node ND4 of the current generation circuit 42 is coupled to an inverting input terminal. The resistor RD is provided between an output terminal of the operational amplifier OPD1 and the inverting input terminal of the operational amplifier OPD1. In FIG. 3, a capacitor CD for phase compensation is provided between the output terminal and the inverting input terminal of the operational amplifier OPD1, but the capacitor CD may not be provided.

As described above, the temperature compensation circuit 40 in FIG. 3 includes the first-order correction circuit 43 and the higher-order correction circuit 44 to which the temperature detection voltage VTS is input, the current generation circuit 42 that generates a temperature compensation current ICP by using the first-order correction circuit 43 and the higher-order correction circuit 44, and the current-voltage conversion circuit 46 that converts the temperature compensation current ICP into a voltage and outputs the temperature compensation voltage VCP. According to the temperature compensation circuit 40 having such a configuration, the temperature compensation current ICP, which is a function current generated by the current generation circuit 42 based on the temperature detection voltage VTS, can be converted into a voltage by the current-voltage conversion circuit 46 and can be output as a temperature compensation voltage VCP.

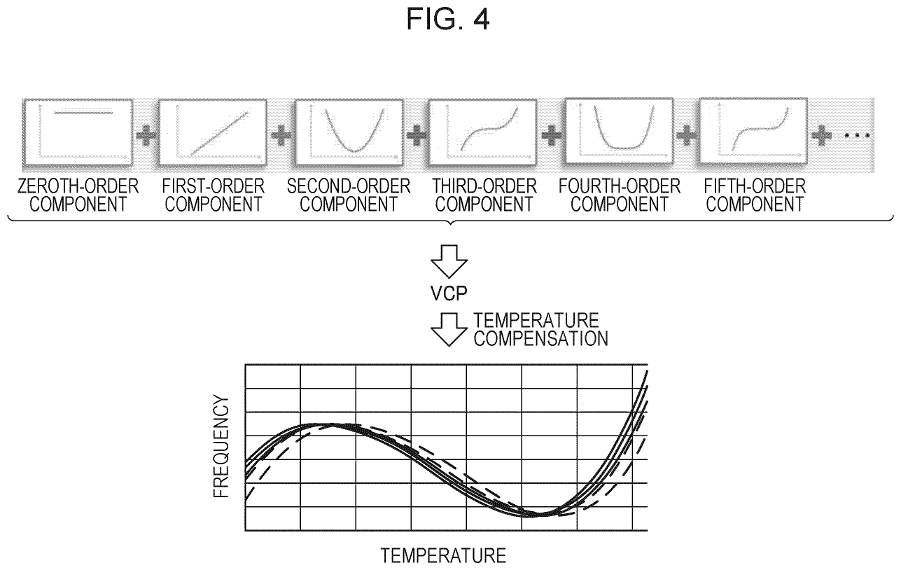

FIG. 4 is an explanatory diagram of temperature compensation. The zeroth-order component, the first-order component, the second-order component, the third-order component, the fourth-order component, and the fifth-order component each have characteristics of a zeroth-order function, a first-order function, a second-order function, a third-order function, a fourth-order function, and a fifth-order function with respect to temperature. The temperature compensation for correcting the first-order component is performed by the first-order correction circuit 43 of FIG. 3, and the temperature compensation for correcting the second-order component, the third-order component, the fourth-order component, and the fifth-order component is performed by the higher-order correction circuit 44. The correction of the second-order component and the fourth-order component may be omitted. By changing the capacitance of the variable capacitance circuit 32 based on the temperature compensation voltage VCP generated by the temperature compensation as shown in FIG. 4, it is possible to cancel the fluctuation of the oscillation frequency of the resonator 10 due to the temperature and to keep the oscillation frequency constant against the temperature change. In this case, process variation occurs in the temperature characteristic of the oscillation frequency of the resonator 10. Therefore, at the time of shipment of the product or the like, a clock frequency of the oscillator 4 is monitored, and appropriate correction data based on the monitoring result is written in the nonvolatile memory 110 of the circuit device 20, so that temperature compensation based on the correction data is performed.

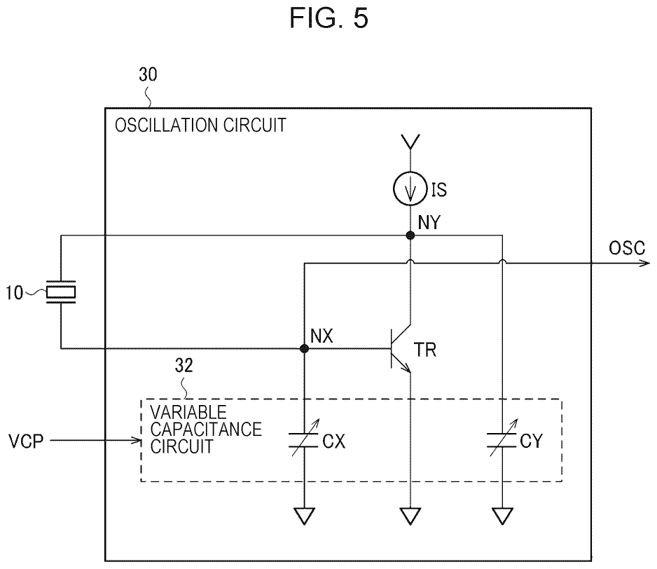

FIG. 5 is a configuration example of the oscillation circuit 30. The configuration of the oscillation circuit 30 is not limited to the configuration of FIG. 5, and various modifications such as omitting some of the components, adding other components, and replacing some of the components with other components can be implemented.

The oscillation circuit 30 of FIG. 5 includes a bipolar transistor TR for driving the resonator 10, a current source IS for supplying a current to the bipolar transistor TR, and the variable capacitance circuit 32. A node NX at one end of the resonator 10 is coupled to the base of the bipolar transistor TR, and a node NY at the other end of the resonator 10 is coupled to a collector of the bipolar transistor TR. In addition, the variable capacitance circuit 32 includes variable capacitance elements CX and CY. The variable capacitance element CX is provided between the node NX and the node VSS, and the variable capacitance element CY is provided between the node NY and the node of VSS. The variable capacitance elements CX and CY are realized by, for example, varactors or the like.

In this case, the variable capacitance circuit 32 is a circuit having, for example, a positive characteristic in a capacitance change characteristic with respect to a capacitance control voltage. The positive characteristic of capacitance change means a change characteristic in which capacitance increases as the capacitance control voltage increases. The change characteristic of the capacitance of the variable capacitance circuit 32 may be a negative characteristic. The temperature compensation circuit 40 supplies the temperature compensation voltage VCP, as the capacitance control voltage, to the variable capacitance circuit 32. Since the variable capacitance circuit 32 is a variable capacitance circuit having a positive characteristic, when the temperature compensation voltage VCP from the temperature compensation circuit 40 increases, capacitance of the variable capacitance circuit 32 increases, and an oscillation frequency of the oscillation circuit 30 decreases. Accordingly, it is possible to realize the temperature compensation for offsetting the increase in the oscillation frequency. Further, when the temperature compensation voltage VCP from the temperature compensation circuit 40 decreases, the capacitance of the variable capacitance circuit 32 decreases, and the oscillation frequency of the oscillation circuit 30 increases. Accordingly, it is possible to realize the temperature compensation for offsetting the decrease in the oscillation frequency. A variable capacitance circuit whose capacitance is controlled by a frequency control voltage input from the outside may be provided in the oscillation circuit 30, and an oscillation frequency may be variable by the frequency control voltage.

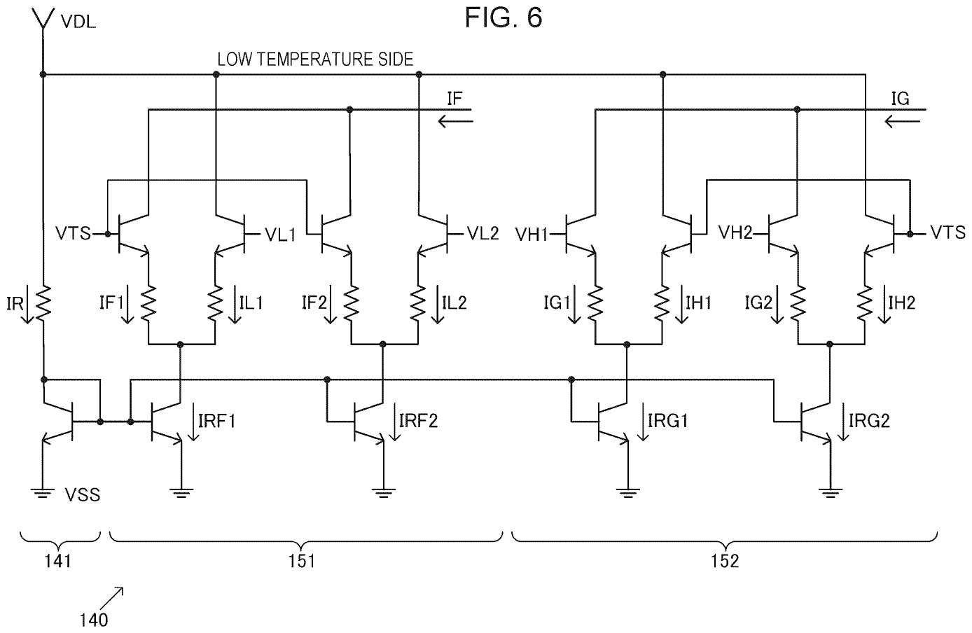

FIG. 6 is a configuration example of a function current generation circuit 140 included in the temperature compensation circuit 40. The function current generation circuit 140 is provided in the higher-order correction circuit 44 of FIG. 3, for example, and generates higher-order function currents such as second-order, third-order, fourth-order, and fifth-order function currents.

As shown in FIG. 6, the function current generation circuit 140 includes a reference current generation circuit 141, a first compensation circuit 151, and a second compensation circuit 152. The reference current generation circuit 141 generates a reference current IR. The first compensation circuit 151 performs temperature compensation in a low-temperature range, which is a first temperature range, and the second compensation circuit 152 performs temperature compensation in a high-temperature range, which is a second temperature range.

The first compensation circuit 151 and the second compensation circuit 152 each include a plurality of differential pair circuits. In each differential pair circuit of the first compensation circuit 151, reference currents IRF1 and IRF2 that mirror the reference current IR flow. In each differential pair circuit of the second compensation circuit 152, reference currents IRG1 and IRG2 that mirror the reference current IR flow. Further, each differential pair circuit includes a first bipolar transistor and a second bipolar transistor that form a differential pair. The temperature detection voltage VTS is input to a base of the first bipolar transistor, and any one of the reference voltages VL1, VL2, VH1, and VH2 is input to a base of the second bipolar transistor. These reference voltages are also generated by the reference voltage generation circuit 60.

A case where two differential pair circuits are included in each of the first compensation circuit 151 and the second compensation circuit 152 is shown in FIG. 6, but the number of differential pair circuits included in each compensation circuit is not limited to this, and the number of differential pair circuits may be three or more. Further, in the case of the configuration of FIG. 6, the polarity of the temperature characteristic of the temperature detection voltage VTS used in the first compensation circuit 151 on the low temperature side and the polarity of the temperature characteristic of the temperature detection voltage VTS used in the second compensation circuit 152 on the high temperature side are set to be different. For example, when the temperature detection voltage VTS having a negative temperature characteristic is used in the first compensation circuit 151 on a low temperature side, the temperature detection voltage VTS having a positive temperature characteristic may be used in the second compensation circuit 152 on a high temperature side.

The first compensation circuit 151 generates a current IF=IF1+IF2 for temperature compensation in the low-temperature range, and the second compensation circuit 152 generates the current IG=IG1+IG2 for temperature compensation in the high-temperature range. In addition, since the reference current IR is a constant current, current values of the reference current IRF1=IF1+IL1 and the reference current IRF2=IF2+IL2 flowing through each differential pair circuit of the first compensation circuit 151 are also constant currents. In addition, current values of the reference current IRG1=IG1+IH1 and the reference current IRG2=IG2+IH2 flowing through each differential pair circuit of the second compensation circuit 152 are constant currents.

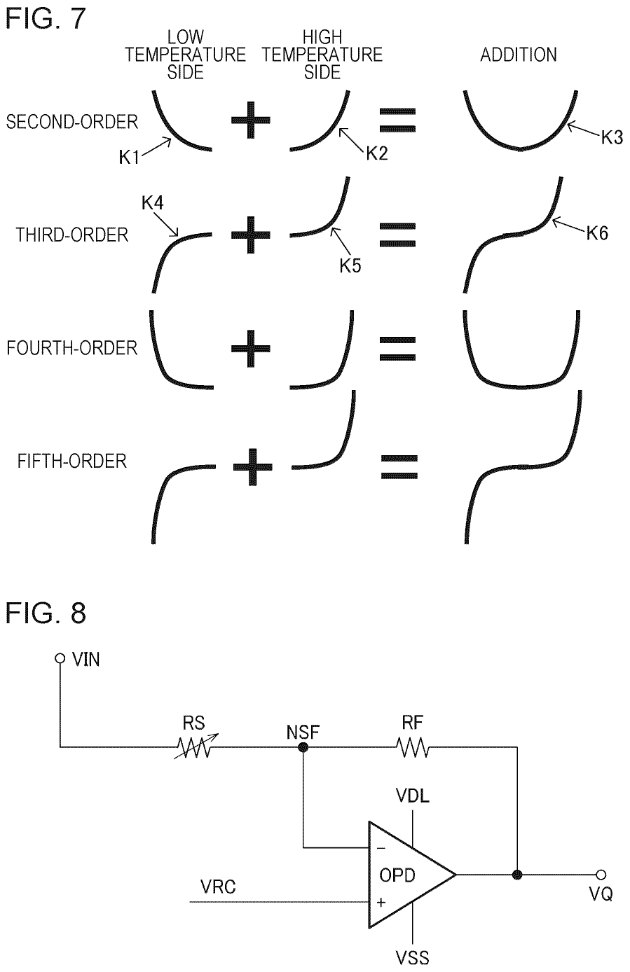

In the low-temperature range, the current IF=IF1+IF2 increases, whereas the current IG=IG1+IG2 decreases. On the other hand, in the high-temperature range, the current IG=IG1+IG2 increases, whereas the current IF=IF1+IF2 decreases. By using the function current generation circuit 140, as shown in FIG. 7, higher-order function currents such as a second-order, third-order, fourth-order, and fifth-order function current can be generated. For example, the current IF flowing through the first compensation circuit 151 in the low-temperature range is set to the characteristic shown in K1 of FIG. 7, and the current IG flowing through the second compensation circuit 152 in the high-temperature range is set to the characteristic shown in K2. Accordingly, the second-order function current as shown in K3 can be generated. In addition, the current IF flowing through the first compensation circuit 151 in the low-temperature range is set to the characteristic shown in K4 of FIG. 7, and the current IG flowing through the second compensation circuit 152 in the high-temperature range is set to the characteristic shown in K5. Accordingly, the third-order function current as shown in K6 can be generated. The fourth-order and fifth-order function currents can also be generated using the same method.

### 2. Temperature Characteristics of Input Limit Voltage and Reference Voltage

In recent years, there is a demand for the power supply voltage VDD to be lowered. When the power supply voltage VDD is lowered, low power consumption of the circuit device 20 and the oscillator 4 and the like can be realized. However, it is found that there is a problem in that it is difficult to secure the output voltage range of the temperature compensation circuit 40 along with reduction in the power supply voltage VDD.

For example, FIG. 8 shows a configuration example of an amplifier circuit included in the temperature compensation circuit 40. The amplifier circuit is an inverting amplifier circuit, and includes an operational amplifier OPD that operates with a power supply voltage VDL supplied as power, and resistors RS and RF. The operational amplifier OPD corresponds to, for example, the operational amplifier OPD1 of FIG. 3, and the resistors RS and RF correspond to the resistors RD3 and RD of FIG. 3. The resistors RS and RF are provided in series between an input node of a voltage VIN and an output terminal of the operational amplifier OPD. In addition, the operational amplifier OPD receives the reference voltage VRC at a non-inverting input terminal, has a coupling node NSF between the resistor RS and the resistor RF coupled to the inverting input terminal, and outputs an output voltage VQ from the output terminal. The non-inverting input terminal is a first input terminal, and the inverting input terminal is a second input terminal. An output voltage VQ of the amplifier circuit of FIG. 8 is represented by the following Equation (1). In the present embodiment, the resistor and the resistance value thereof are represented by the same reference sign. For example, resistance values of the resistors RS and RF are also represented by RS and RF.

$$VQ = - \frac{RF}{RS} VIN + ( 1 + \frac{RF}{RS} ) VRC \qquad ( 1 )$$

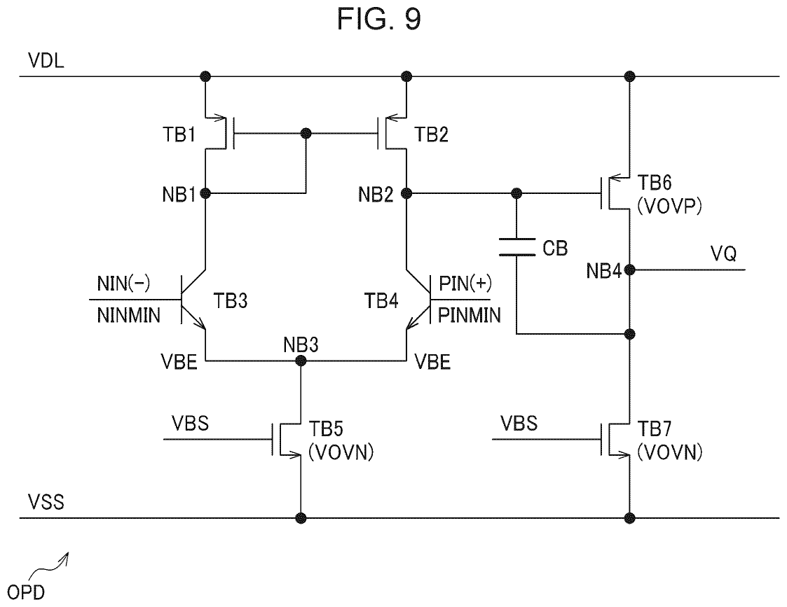

FIG. 9 shows a configuration example of the operational amplifier OPD. A differential portion of the operational amplifier OPD of FIG. 9 includes transistors TB1 and TB2 that constitute a current mirror circuit, bipolar transistors TB3 and TB4 that are transistors of a differential pair, and a transistor TB5 that is a current source. The P-type transistors TB1 and TB2 are provided between the node of VDL and nodes NB1 and NB2, and a gate is coupled to the node NB1. The npn bipolar transistor TB3 is provided between the node NB1 and the node NB3, and a voltage NIN from the inverting input terminal is input to the base. The npn bipolar transistor TB4 is provided between the node NB2 and the node NB3, and a voltage PIN from the non-inverting input terminal is input to the base. A modification using the N-type MOS transistor instead of npn bipolar transistors TB3 and TB4 can be implemented. The N-type transistor TB5 is provided between the node NB3 and the node of VSS, and a bias voltage VBS is input to the gate.

An output portion of the operational amplifier OPD includes transistors TB6 and TB7 provided in series between the node of VDL and the node of VSS. A gate of the P-type transistor TB6 is coupled to the node NB2, which is the output node of the differential portion, and the bias voltage VBS is input to a gate of the N-type transistor TB7. The output voltage VQ is output from the node NB4 between the transistor TB6 and the transistor TB7. A capacitor CB is a capacitor for phase compensation.

Here, base-emitter voltages of the bipolar transistors TB3 and TB4 of FIG. 9 are defined as VBE. In addition, an overdrive voltage of the N-type transistor TB5 is defined as VOVN. In addition, an input lower limit voltage of the first input terminal of the operational amplifier OPD is defined as PINMIN, and an input lower limit voltage of the second input terminal of the operational amplifier OPD is defined as NINMIN. The first input terminal of the operational amplifier OPD corresponds to a base of the bipolar transistor TB4, and the second input terminal corresponds to a base of the bipolar transistor TB3. Then, the relationship of the following Equation (2) is established for the input lower limit voltages PINMIN and NINMIN.

$$PIN MIN = NINM IN = VBE + VOVN \qquad ( 2 )$$

When the above Equation (2) is established, it is guaranteed that the bipolar transistors TB3 and TB4 operate in the active region and the transistor TB5 operates in the saturation region.

In addition, an overdrive voltage of the P-type transistor TB6 is defined as VOVP, and the maximum voltage of the output voltage VQ of the operational amplifier OPD is defined as VQMAX. Then, the relationship of the following Equation (3) is established.

$$VQ MAX = VDL - VOVP \qquad ( 3 )$$

Therefore, when the power supply voltage VDD of the circuit device 20 decreases and the power supply voltage VDL of the operational amplifier OPD of the temperature compensation circuit 40 decreases, the maximum voltage VQMAX of the output voltage VQ of the operational amplifier OPD also decreases, and the output voltage range of the operational amplifier OPD is limited.

Here, for example, when a threshold voltage of the transistor is defined as Vth, a gate-source voltage is defined as VGS, and a drain-source voltage is defined as VDS, an overdrive voltage can be expressed as VOV=VGS-Vth, and is an index indicating how much VGS exceeds Vth. In order to operate a transistor in the saturation region, VDS>VOV is required. The overdrive voltage VOV (VOVN, VOVP) when the transistor operates in the saturation region is, for example, about 0.1 to 0.2 V.

As shown in FIG. 8, the reference voltage VRC is input to the first input terminal of the operational amplifier OPD. At this time, a voltage of the second input terminal of the operational amplifier OPD due to the virtual ground also becomes the same voltage as VRC. Therefore, in order for the operational amplifier OPD to operate properly, it is necessary to set the reference voltage VRC input to the first input terminal to a voltage equal to or higher than the input lower limit voltage PINMIN, and a relationship of the following Equation (4) needs to be established.

$$VRC \geq PIN MIN = NIN MIN = VBE + VOVN \qquad ( 4 )$$

In addition, the temperature compensation voltage VCP described in FIG. 4 is a voltage that varies to a positive side or a negative side around the reference voltage VRC in accordance with the temperature change, and a change voltage to the positive side from the reference voltage VRC and a change voltage to the negative side from the reference voltage VRC are substantially equal. Therefore, a voltage range of the temperature compensation voltage VCP can be represented as in the following Equation (5).

$$VRC \pm ( VQ MAX - VRC ) \qquad ( 5 )$$

For example, it is assumed that the usage temperature range defined by the specifications of the circuit device 20 or the oscillator 4 is, for example, −40° C. to 105° C. At this time, VBE, which is the base-emitter voltage of the bipolar transistors TB4 and TB3, is, for example, about 0.4 V at a typical temperature of 25° C. In addition, VBE is, for example, about 0.6 V at −40° C., which is the lower limit temperature of the usage temperature range, and is, for example, about 0.3 V at 105° C., which is the upper limit temperature of the usage temperature range. That is, VBE, which is the base-emitter voltage, has a negative temperature characteristic. The usage temperature range is a temperature range for temperature compensation. Here, the usage temperature range is defined as −40° C. to 105° C. as an example; however, the present disclosure is not limited thereto, and the usage temperature range may be, for example, −40° C. to 125° C. or 0° C. to 85° C.

For example, it is assumed that an overdrive voltage of the transistor TB5 is VOVN=0.1 V. Then, according to the above Equation (2), PINMIN and NINMIN, which are the input lower limit voltages, are 0.4+0.1=0.5 V at the typical temperature, 0.6+0.1=0.7 V at the lower limit temperature of the usage temperature range, and 0.3+0.1=0.4 V at the upper limit temperature. According to the above Equation (4), the reference voltage VRC input to the first input terminal of the operational amplifier OPD needs to be a voltage equal to or higher than the input lower limit voltages PINMIN and NINMIN. Therefore, in order to properly operate the operational amplifier OPD in the usage temperature range, it is necessary to set the reference voltage VRC to a voltage equal to or higher than the input lower limit voltage PINMIN=NINMIN=0.7 V at the lower limit temperature of the usage temperature range.

In addition, the power supply voltage VDL of the operational amplifier OPD is generated, for example, by regulating the power supply voltage VDD supplied from the outside by the regulator of the power supply circuit 90 of FIG. 2. When the power supply voltage VDD is lowered and VDD=1.1 V, the power supply voltage of the operational amplifier OPD becomes, for example VDL=1.0 V. Then, when it is assumed that an overdrive voltage of the transistor TB6 is VOVP=0.1 V, the maximum voltage of the output voltage VQ of the operational amplifier OPD is VQMAX=VDL-VOVP=1.0−0.1=0.9 V by the above Equation (3). Therefore, in this case, the voltage range of the temperature compensation voltage VCP according to the above Equation (5) is VRC± (VQMAX−VRC)=0.7± (0.9−0.7)=0.7±0.2 V.

In this case, when the power supply voltage VDD is sufficiently high and the power supply voltage VDL of the operational amplifier OPD is also high, the VQMAX can be increased from the above Equation (3). Therefore, the voltage range of the temperature compensation voltage VCP can be sufficiently widened. However, when the power supply voltage VDD is lowered, the voltage range of the temperature compensation voltage VCP becomes narrow, for example, to 0.7±0.2 V, as compared with a case where the power supply voltage VDD is high, as described above.

Even when the voltage range of the temperature compensation voltage VCP is narrowed as described above, as a method of realizing appropriate temperature compensation, a method of increasing the capacitance of the variable capacitance elements CX and CY of the variable capacitance circuit 32 of FIG. 5 to increase a sensitivity KV is considered. The sensitivity represents a change in the frequency with respect to a capacitance control voltage which is the temperature compensation voltage VCP. However, when the capacitance of the variable capacitance elements CX and CY is increased to increase the sensitivity KV, the variation and fluctuation of the capacitance of the variable capacitance elements CX and CY become large, which causes problems such as complicating temperature compensation and increasing noise superimposed on the temperature compensation voltage VCP.

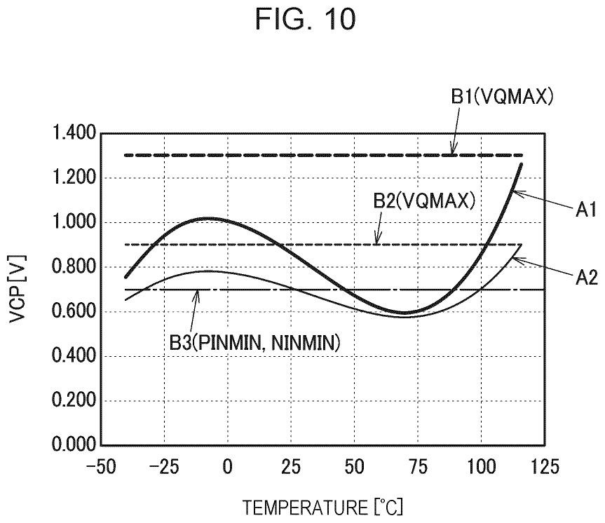

For example, A1 and A2 of FIG. 10 are examples of the temperature characteristic of the temperature compensation voltage VCP when the power supply voltage is 1.4 V. In A1 of FIG. 10, sensitivities of the variable capacitance elements CX and CY are set to KV=50 [ppm/V], and the reference voltage is set to VRC=0.85 V. In A2 of FIG. 10, the sensitivity is set to KV=100 [ppm/V], and the reference voltage is set to VRC=0.7 V. In addition, B1 of FIG. 10 indicates the maximum voltage VQMAX of the temperature compensation voltage VCP when the power supply voltage is 1.4 V, and VQMAX=1.3 V. B2 indicates the maximum voltage VQMAX when the power supply voltage is 1.0 V, and VQMAX=0.9 V. Further, B3 indicates the input lower limit voltage PINMIN=NINMIN=0.7 V when the lower limit temperature is −40° C.

When the power supply voltage is high and the maximum voltage VQMAX is high as shown in B1 of FIG. 10, a voltage range of the temperature compensation voltage VCP can be widened as shown in A1. However, when the power supply voltage is low and the maximum voltage VQMAX is low as shown in B2 of FIG. 10, a voltage range of the temperature compensation voltage VCP becomes narrow as shown in A2. Therefore, even when the sensitivity KV is increased, there is a problem in that appropriate temperature compensation cannot be realized.

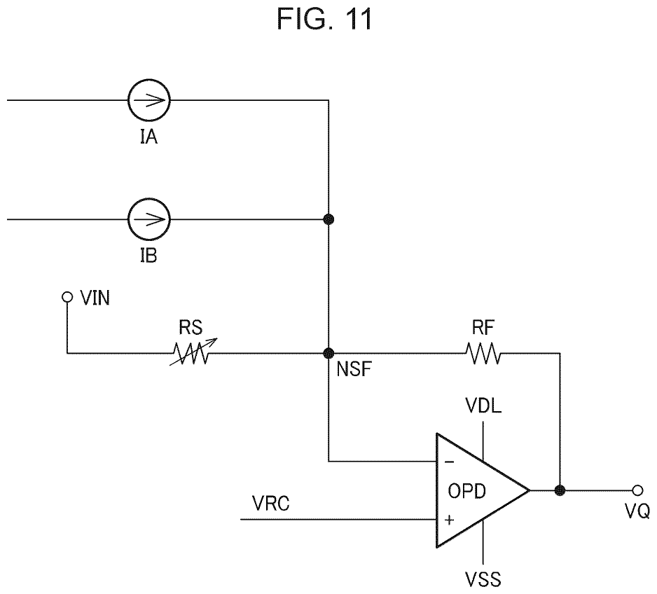

FIG. 11 is a diagram schematically showing an amplifier circuit of current-voltage conversion of the temperature compensation circuit 40. Currents IA and IB of FIG. 11 correspond to the temperature compensation currents. The output voltage VQ of the amplifier circuit of the current-voltage conversion of FIG. 11 is represented by the following Equation (6).

$$VQ = - \frac{RF}{RS} VIN + IA \cdot RF + IB \cdot RF + ( 1 + \frac{RF}{RS} ) VRC \qquad ( 6 )$$

In the temperature compensation circuit 40, IA and IB corresponding to the temperature compensation current are set to be 0 when VIN=VRC in the above Equation (6). In this way, the inflection points in the temperature compensation can be aligned. That is, as described in FIG. 6, in the function current generation circuit 140 of the temperature compensation circuit 40, the first compensation circuit 151 generates a current IF=IF1+IF2 for temperature compensation in the low-temperature range, and the second compensation circuit 152 generates the current IG=IG1+IG2 for temperature compensation in the high-temperature range. In the low-temperature range, the current IF increases, whereas the current IG decreases and becomes 0. In addition, in the high-temperature range, the current IG increases, whereas the current IF decreases and becomes 0. At a typical temperature at which VCP=VRC, the currents IG and IF become 0, and the currents IA and IB of FIG. 11 become 0. As a result, it is possible to align an inflection point between K1 and K2 and an inflection point between K4 and K5 in FIG. 7.

In the temperature compensation circuit 40, VIN from the first-order correction circuit 43 has a first-order temperature characteristic. Therefore, even when the reference voltage VRC has a first-order temperature characteristic, as will be described in detail later, the first-order correction circuit 43 can perform correction for canceling the influence of the first-order temperature characteristic of the reference voltage VRC.

Therefore, in the present embodiment, when the input limit voltage PINLM of the first input terminal of the operational amplifier OPD has the temperature characteristic of the first polarity, the reference voltage VRC input to the first input terminal also has a temperature characteristic of a first polarity having the same as the polarity of the temperature characteristic of the input limit voltage PINLM.

For example, as described in FIG. 9 and the above Equation (2), since VBE, which is the base-emitter voltage of the bipolar transistor TB3, has a negative temperature characteristic, the input lower limit voltage PINMIN=VBE+VOVN of the first input terminal of the operational amplifier OPD also has a negative temperature characteristic. For example, the input lower limit voltage PINMIN is 0.7 V at −40° C. and 0.4 V at 105° C., and decreases as the temperature increases. Therefore, the reference voltage VRC input to the first input terminal of the operational amplifier OPD also has the same negative temperature characteristic as the input lower limit voltage PINMIN. That is, it is common to input the reference voltage VRC having a constant voltage that does not change according to the temperature change to the first input terminal of the operational amplifier OPD. However, in the present embodiment, contrary to this, the reference voltage VRC having a negative temperature characteristic is input to the first input terminal.

In this way, by inputting the reference voltage VRC having a negative temperature characteristic to the first input terminal of the operational amplifier OPD, it is possible to expand an output voltage range of the operational amplifier OPD, and it is possible to realize an appropriate temperature compensation. As will be described in detail later, even when the reference voltage VRC having a negative temperature characteristic is input to the first input terminal of the operational amplifier OPD, the first-order correction circuit 43 of the temperature compensation circuit 40 can also perform correction to cancel the influence caused by the negative temperature characteristic of the reference voltage VRC.

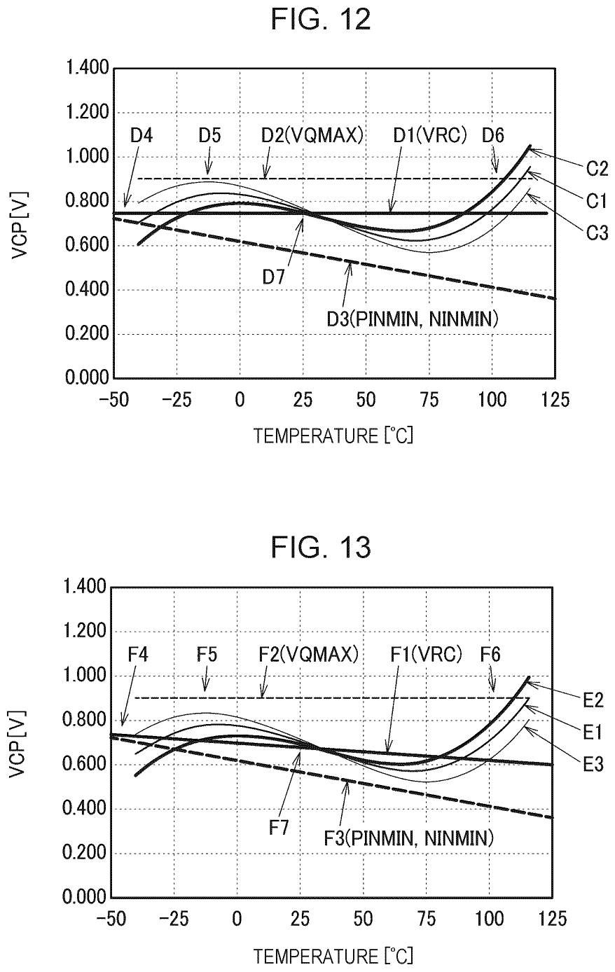

FIG. 12 is an example of a temperature characteristic for describing a method of a comparative example. As shown in C1, C2, and C3 of FIG. 12, the temperature characteristic of the temperature compensation voltage VCP changes in response to the process fluctuation. For example, the clock frequency of the oscillator 4 is monitored at the time of shipment or the like, the correction data is written in the nonvolatile memory 110 based on the monitoring result, and the temperature compensation circuit 40 generates the temperature compensation voltage VCP based on the correction data. In the comparative example, as shown in D1, the reference voltage VRC does not have a negative temperature characteristic, and has a flat temperature characteristic in which the reference voltage VRC does not change with a temperature change and becomes a constant voltage, and is set to, for example, VRC=0.75 V. For example, since the power supply voltage is VDD=1.1 V and VDL=1.0 V, the maximum voltage of the temperature compensation voltage VCP, that is, VQMAX=VDL−VOVP is 0.9 V as shown in D2. In addition, as shown in D3, the input lower limit voltage PINMIN=VBE+VOVN has a negative temperature characteristic.

As described in the above Equation (4), in the usage temperature range, which is the temperature compensation range, the reference voltage VRC needs to be set to a voltage equal to or higher than the input lower limit voltage PINMIN. As shown in D3 of FIG. 12, PINMIN has a negative temperature characteristic. Therefore, as shown in D4, the reference voltage VRC is set to satisfy the relationship of VRC≥PINMIN at the lower limit temperature of the usage temperature range.

However, in the method of the comparative example of FIG. 12, when the temperature characteristic of the temperature compensation voltage VCP is as shown in C2 or C3, for example, in D5 or D6, there is a possibility that the temperature compensation voltage VCP exceeds the maximum voltage VQMAX. Therefore, there is a problem in that the voltage range of the temperature compensation voltage VCP cannot be widened and appropriate temperature compensation cannot be realized.

FIG. 13 is an example of a temperature characteristic describing the method of the present embodiment. In FIG. 13, as shown in E1, E2, and E3, the temperature characteristic of the temperature compensation voltage VCP changes in response to the process fluctuation. In the present embodiment, as shown in F1, the reference voltage VRC has a negative temperature characteristic, and the reference voltage VRC decreases as the temperature increases. In addition, as shown in F2, VQMAX=VDL−VOVP, which is the maximum voltage of the temperature compensation voltage VCP, is 0.9 V.

In addition, as shown in F3 of FIG. 13, the input lower limit voltage PINMIN has a negative temperature characteristic similar to the reference voltage VRC. However, a slope of the first-order temperature characteristic of the reference voltage VRC is smaller than a slope of the first-order temperature characteristic of the input lower limit voltage PINMIN. As shown in F4, the reference voltage VRC is set to satisfy the relationship of VRC≥PINMIN at the lower limit temperature of the usage temperature range. In addition, even when the temperature characteristic of the temperature compensation voltage VCP becomes a characteristic as shown in E2 or E3, the temperature compensation voltage VCP does not exceed the maximum output voltage VQMAX of the operational amplifier OPD, as shown in F5 or F6.

That is, in the comparative example of FIG. 12, as shown in D1, the reference voltage VRC has a flat temperature characteristic in the usage temperature range. The reference voltage VRC is set to, for example, 0.75 V such that the reference voltage VRC is equal to or higher than the input lower limit voltage PINMIN at the lower limit temperature of the usage temperature range shown in D4. Therefore, even at a typical temperature (25° C.) shown in D7, the reference voltage VRC is 0.75 V, and the temperature compensation voltage VCP is a voltage that changes around the reference voltage VRC=0.75 V. Therefore, there is a possibility that the temperature compensation voltage VCP exceeds the maximum voltage VQMAX as in D5 or D6.

On the other hand, in the present embodiment of FIG. 13, as shown in F1, the reference voltage VRC has a negative temperature characteristic similar to the input lower limit voltage PINMIN. Therefore, at a lower limit temperature shown in F4, when the reference voltage VRC is set to be equal to or higher than the input lower limit voltage PINMIN, the reference voltage at the typical temperature is set to VRC=0.7 V as shown in F7. That is, as compared with the comparative example of FIG. 12, it is possible to lower the reference voltage VRC at the typical temperature by about 50 mV, for example. That is, in D7 of FIG. 12 in the comparative example, the reference voltage VRC is 0.75 V, whereas in F7 of FIG. 13 in the present embodiment, the reference voltage VRC becomes 0.7 V, and a temperature characteristic of the temperature compensation voltage VCP becomes a characteristic that is lower as a whole by about 50 mV as compared with that in the comparative example. Therefore, for example, in F5 and F6, it is possible to suppress the temperature compensation voltage VCP from exceeding the maximum voltage VQMAX, and it is possible to realize appropriate temperature compensation as compared with the comparative example.

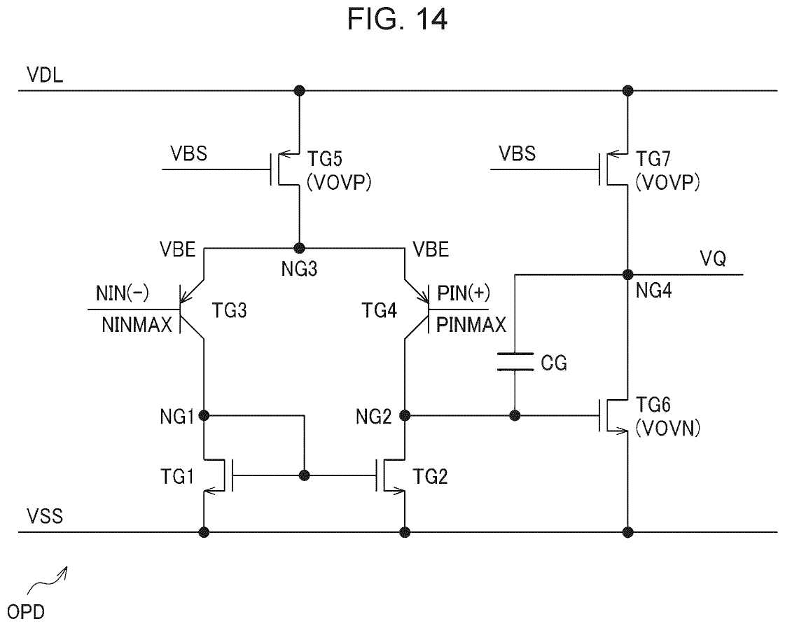

FIG. 14 shows another configuration example of the operational amplifier OPD. While FIG. 9 is the configuration example of the operational amplifier OPD of the Nch input stage and the Pch output stage, FIG. 14 is a configuration example of the operational amplifier OPD of the Pch input stage and the Nch output stage. A differential portion of the operational amplifier OPD of FIG. 14 includes transistors TG1 and TG2 that constitute a current mirror circuit, bipolar transistors TG3 and TG4 that are transistors of a differential pair, and a transistor TG5 that is a current source. N-type transistors TG1 and TG2 are provided between nodes NG1 and NG2 and the node of VSS, and gates are coupled to the node NG1. The pnp bipolar transistor TG3 is provided between a node NG3 and the node NG1, and the voltage NIN from the inverting input terminal is input to a base. The pnp bipolar transistor TG4 is provided between the node NG3 and the node NG2, and the voltage PIN from the non-inverting input terminal is input to a base. A modification using the P-type MOS transistor instead of bipolar transistors TG3 and TG4 can be implemented. The P-type transistor TG5 is provided between the node of VDL and the node NG3, and the bias voltage VBS is input to a gate.

An output portion of the operational amplifier OPD includes transistors TG7 and TG8 provided in series between the node of VDL and the node of VSS. A gate of the N-type transistor TG6 is coupled to the node NG2, which is the output node of the differential portion, and the bias voltage VBS is input to a gate of the P-type transistor TG7. The output voltage VQ is output from a node NG4 between the transistor TG7 and the transistor TG6. A capacitor CG is a capacitor for phase compensation.

Here, base-emitter voltages of the bipolar transistors TG3 and TG4 of FIG. 14 are defined as VBE. In addition, an overdrive voltage of the P-type transistor TG5 is defined as VOVP. In addition, an input upper limit voltage of the first input terminal of the operational amplifier OPD is defined as PINMAX, and an input upper limit voltage of the second input terminal of the operational amplifier OPD is defined as NINMAX. The first input terminal of the operational amplifier OPD corresponds to a base of the bipolar transistor TG4, and the second input terminal corresponds to a base of the bipolar transistor TG3. Then, the relationship of the following Equation (7) is established for the input upper limit voltages PINMAX and NINMAX.

$$PIN MAX = NIN MAX = VDL - VBE - VOVP \qquad ( 7 )$$

In the above Equation (7), since VBE, which is the base-emitter voltage, has a negative temperature characteristic, the input upper limit voltages PINMAX and NINMAX have a positive temperature characteristic.

In addition, an overdrive voltage of the N-type transistor TG6 is defined as VOVN, and the minimum voltage of the output voltage VQ of the operational amplifier OPD is defined as VQMIN. Then, the relationship of the following Equation (8) is established.

$$VQ MIN = VOVN \qquad ( 8 )$$

In order for the operational amplifier OPD to operate properly, it is necessary to set the reference voltage VRC input to the first input terminal to a voltage equal to or lower than the input upper limit voltage PINMAX, and a relationship of the following Equation (9) needs to be established.

$$VRC \leq PIN MAX = NIN MAX = VDL - VBE - VOVP \qquad ( 9 )$$

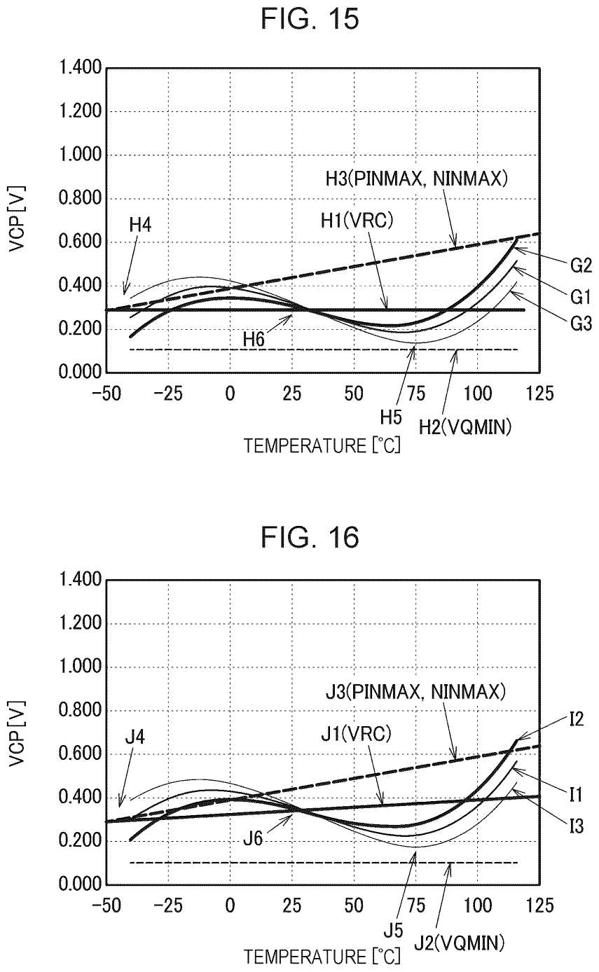

FIG. 15 is an example of a temperature characteristic describing a method of the comparative example in the configuration of the operational amplifier OPD of FIG. 14. In FIG. 15, as shown in G1, G2, and G3, the temperature characteristic of the temperature compensation voltage VCP changes in response to the process fluctuation. In the comparative example, as shown in H1, the reference voltage VRC has a flat temperature characteristic and is set to VRC=0.3 V, for example. As shown in H2, VQMIN=VOVN, which is the minimum voltage of the temperature compensation voltage VCP, is 0.1 V. In addition, as shown in H3, PINMAX=VDL−VBE−VOVP, which is the input upper limit voltage, has a positive temperature characteristic. The voltage range of the temperature compensation voltage VCP can be represented by VRC+ (VQMIN−VRC).

As described in the above Equation (9), the reference voltage VRC needs to be set to a voltage equal to or lower than the input upper limit voltage PINMAX in the usage temperature range, and as shown in H3, PINMAX has a positive temperature characteristic. Therefore, as shown in H4, at the lower limit temperature, the reference voltage VRC is set to satisfy the relationship of VRC≤PINMAX. In the method of the comparative example of FIG. 15, when the temperature characteristic of the temperature compensation voltage VCP is the characteristic as shown in G3, there is a possibility that the temperature compensation voltage VCP may fall below the minimum voltage VQMIN as shown in H5.

FIG. 16 is an example of a temperature characteristic describing a method of the present embodiment in the configuration of the operational amplifier OPD of FIG. 14. In FIG. 16, as shown in I1, I2, and I3, the temperature characteristic of the temperature compensation voltage VCP changes in response to the process fluctuation. In the present embodiment, as shown in J1, the reference voltage VRC has a positive temperature characteristic, and the reference voltage VRC increases as the temperature increases. In addition, as shown in J2, VQMIN=VOVN, which is the minimum voltage of the temperature compensation voltage VCP, is 0.1 V.

In addition, as shown in J3, the input upper limit voltage PINMAX has a positive temperature characteristic similar to the reference voltage VRC. However, a slope of the first-order temperature characteristic of the reference voltage VRC is smaller than a slope of the first-order temperature characteristic of the input upper limit voltage PINMAX. In addition, as shown in J4, at the lower limit temperature, the reference voltage VRC is set to satisfy the relationship of VRC≤PINMAX. Even when the temperature characteristic of the temperature compensation voltage VCP is a characteristic as shown in I3, the temperature compensation voltage VCP does not fall below the minimum output voltage VQMIN of the operational amplifier OPD as shown in J5.

That is, in the comparative example of FIG. 15, as shown in H1, the reference voltage VRC has a flat temperature characteristic, and the reference voltage VRC is set to, for example, 0.3 V such that the reference voltage VRC is equal to or lower than the input upper limit voltage PINMAX at the lower limit temperature shown in H4. Therefore, even at a typical temperature shown in H6, the reference voltage VRC is 0.3 V, and the temperature compensation voltage VCP is a voltage that changes around the reference voltage VRC=0.3 V. Therefore, as shown in H5, there is a possibility that the temperature compensation voltage VCP falls below the minimum voltage VQMIN.

On the other hand, in the present embodiment of FIG. 16, as shown in J1, the reference voltage VRC has a positive temperature characteristic similar to the input upper limit voltage PINMAX. Therefore, at the lower limit temperature shown in J4, when the reference voltage VRC is set to be equal to or lower than the input upper limit voltage PINMAX, the reference voltage at the typical temperature is VRC=0.35 V as shown in J6. That is, as compared with the comparative example of FIG. 15, it is possible to increase the reference voltage VRC at the typical temperature by 50 mV, for example. Therefore, in J5, it is possible to suppress the temperature compensation voltage VCP from falling below the minimum voltage VQMIN, and it is possible to realize the appropriate temperature compensation as compared with the comparative example.

### 3. Reference Voltage Generation Circuit

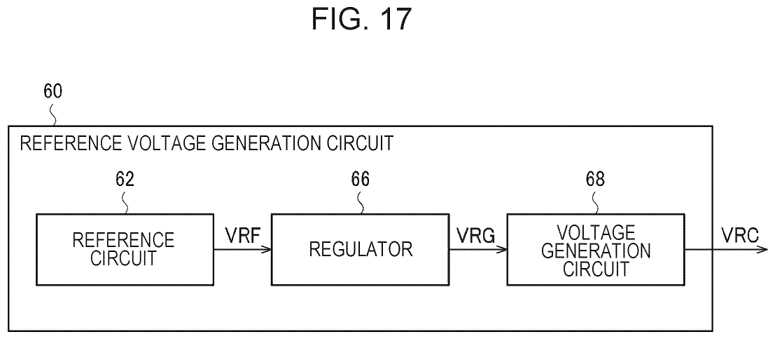

FIG. 17 shows a configuration example of the reference voltage generation circuit 60. The reference voltage generation circuit 60 includes the reference circuit 62, the regulator 66, and the voltage generation circuit 68. The configuration of the reference voltage generation circuit 60 is not limited to the configuration of FIG. 17, and various modifications can be made such as omitting some of the components, adding other components, and replacing some of the components with other components. For example, a modification in which the regulator 66 and the voltage generation circuit 68 are not provided in the reference voltage generation circuit 60 is also possible.

The reference circuit 62 generates a voltage VRF which is a reference voltage. For example, the voltage VRF is a voltage having a temperature characteristic of a first polarity. The reference voltage generation circuit 60 generates a reference voltage VRC having the temperature characteristic of the first polarity based on the voltage VRF. In the case of F1 of FIG. 13, the first polarity is a negative polarity, and in the case of J1 of FIG. 16, the first polarity is a positive polarity.

The regulator 66 generates a voltage VRG which is a regulated voltage based on the voltage VRF. For example, the regulator 66 generates a voltage VRG by regulating the power supply voltage VDD of the circuit device 20 based on the voltage VRF.

Then, the voltage generation circuit 68 generates a reference voltage VRC based on the voltage VRG. For example, the voltage generation circuit 68 generates a reference voltage VRC using the voltage VRG as a reference power supply voltage. For example, the voltage generation circuit 68 generates a reference voltage VRC by voltage-dividing the voltage VRG, which is the reference power supply voltage, by using a resistor circuit. In this case, the voltage generation circuit 68 may generate a plurality of reference voltages having different voltage levels based on the voltage VRG. For example, the voltage generation circuit 68 generates a reference voltage used in the function current generation circuit 140 of FIG. 6 included in each correction circuit such as the third-order correction circuit and the fifth-order correction circuit included in the higher-order correction circuit 44 of FIG. 3. For example, the voltage generation circuit 68 generates reference voltages corresponding to the voltages VL1, VL2, VH1, and VH2 in FIG. 6.

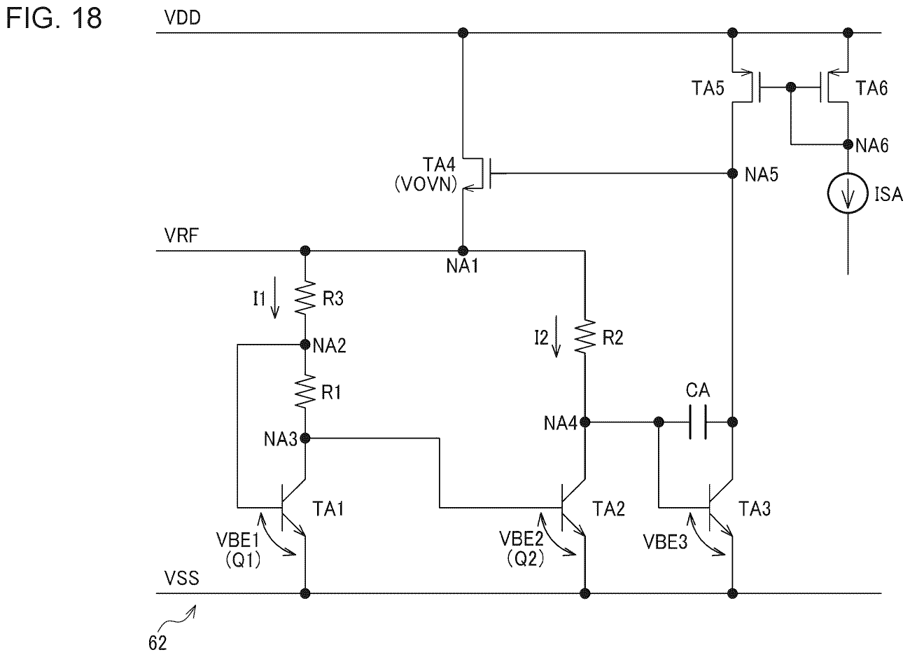

FIG. 18 shows a configuration example of the reference circuit 62. The reference circuit 62 is a bandgap reference circuit (BGR circuit), and more specifically, a Widlar type BGR circuit. The reference circuit 62 includes npn bipolar transistors TA1, TA2, and TA3, the resistors R1, R2, and R3, an N-type MOS transistor TA4, P-type MOS transistors TA5 and TA6, and a capacitor CA. The configuration of the reference circuit 62 is not limited to the configuration of FIG. 18, and various modifications such as omitting some of the components, adding other components, and replacing some of the components with other components can be implemented.

The resistors R3 and R1 and the bipolar transistor TA1 are provided in series between a node NA1 of the voltage VRF and a node of VSS (GND). Then, in the bipolar transistor TA1, a base is coupled to a node NA2 between the resistor R3 and the resistor R1, a collector is coupled to a node NA3 at one end of the resistor R1, and an emitter is coupled to the node of VSS.

In addition, the resistor R2 and the bipolar transistor TA2 are provided in series between the node NA1 of the voltage VRF and the node of VSS. Then, in the bipolar transistor TA2, a base is coupled to the node NA3, a collector is coupled to a node NA4 at one end of the resistor R2, and an emitter is coupled to the node of VSS. In the bipolar transistor TA3, a base is coupled to the node NA4, a collector is coupled to a node NA5, and an emitter is coupled to the node of VSS. The capacitor CA is provided between the node NA4 and the node NA5.

The N-type transistor TA4 is provided between a node of VDD and the node NA1, and a gate is coupled to the node NA5. The P-type transistors TA5 and TA6 constitute a current mirror circuit, and a current of a current source ISA coupled to a drain of the transistor TA6 is mirrored to the transistor TA5 and flows to the bipolar transistor TA3.

For example, when a collector current of the bipolar transistor is IC and the saturation current is IS, a base-emitter voltage is represented by VBE=(kT/q)·ln(IC/IS)=VT·ln(IC/IS). Here, k is a Boltzmann constant, T is a temperature, and q is an electric charge of an electron. In addition, when the number of parallel bipolar transistors is represented by Q, the saturation current is represented by IS=Q·IS0.

Here, the number of parallel bipolar transistor TA1 and that of the bipolar transistor TA2 in FIG. 18 are defined as Q1 and Q2, respectively, and the collector currents IC flowing through the bipolar transistors TA1 and TA2 are defined as I1 and I2, respectively. Then, a base-emitter voltage of the bipolar transistor TAL is represented by VBE1=VT·ln{I1/(Q1·IS0)}, and a base-emitter voltage of the bipolar transistor TA2 is represented by VBE2=VT·ln{I2/(Q2·IS0)}. Therefore, when ΔVBE=VBE1−VBE2, ΔVBE=VT·ln{(Q2/Q1)·(I1/I2)} is represented.

Since a voltage across the resistor R1 is VBE1−VBE2=ΔVBE, I1=ΔVBE/R1. Therefore, the voltage VRF=VBE1+I1·R3 is represented as in the following Equation (10).

$$VRF = VBE 1 + \frac{R 3}{R 1} Δ VBE = VBE 1 + \frac{R 3}{R 1} \cdot VT \cdot ln ( \frac{Q 2}{Q 1} \cdot \frac{I 1}{I 2} ) \qquad ( 10 )$$

The first term VBE1 of the above-described Equation (10) has a negative temperature characteristic. On the other hand, the second term (R3/R1) ΔVBE has a positive temperature characteristic. Since the first term VBE1 is determined as a physical quantity, it is possible to cancel the negative temperature characteristic of the first term by adjusting the second term. As a result, it is possible to generate a voltage VRF having a flat temperature characteristic with a minimum fluctuation in the usage temperature range. By canceling the negative temperature characteristic of the first term of the above Equation (10) with the positive temperature characteristic of the second term in this manner, the voltage VRF when the voltage VRF has a flat temperature characteristic is about 1.25 V. That is, by adjusting the voltage VRF to be around 1.25, it is possible to generate the voltage VRF having a flat temperature characteristic. The adjustment of the voltage VRF is performed by adjusting the resistance value of R3 in the second term of the above Equation (10) and the like. When the adjusted voltage VRF is lower than 1.25 V, VRF has a negative temperature characteristic, and when the adjusted voltage VRF exceeds 1.25 V, VRF has a positive temperature characteristic.

Therefore, when the reference voltage generation circuit 60 generates a reference voltage VRC having a negative temperature characteristic based on the voltage VRF of the reference circuit 62, the voltage VRF may be adjusted to a voltage lower than 1.25 V.

The reason why the bipolar transistor TA3 is further provided in FIG. 18 is to perform a first role of determining an operating point of the bipolar transistor TA2 and a second role of adjusting the load current flowing through the load circuit to which the voltage VRF is supplied. That is, by providing the bipolar transistor TA3, it is possible to prevent a collector-emitter voltage of the bipolar transistor TA2 from decreasing and to operate the bipolar transistor TA2 in an active region. Accordingly, the above-described first role is realized. In addition, when a load current IL of VRF flows, the gate voltage of the transistor TA4 is adjusted by the bipolar transistor TA3, and feedback is applied so that the voltage VRF becomes constant. Accordingly, the above-described second role is realized. For example, when the bipolar transistor TA3 operates in the active region, VBE3, which is the base-emitter voltage of the bipolar transistor TA3, becomes constant. Therefore, even when the load current IL changes, a current I2 flowing through the bipolar transistor TA2 does not change, and the increase in the load current IL flows from the transistor TA4.

For example, when a current flowing through the transistor TA4 is defined as ITA4, ITA4=I1+I2+IL. In the reference circuit 62 of FIG. 18, when the bipolar transistors TA1, TA2, and TA3 operate in the active region and the transistor TA4 operates in the saturation region, a current I1 and the current I2 are uniquely determined, and thus the voltage VRF is constant.

That is, when the load current IL increases, the gate voltage VG of the transistor TA4 increases by the feedback using the bipolar transistor TA3, and VG-VRF, which is the gate-source voltage of the transistor TA4, increases. Accordingly, the increase in the load current IL flows to the transistor TA4. On the other hand, when the load current IL decreases, the gate voltage VG decreases, the gate-source voltage VG-VRF also decreases, and the current flowing through the transistor TA4 also decreases. Accordingly, the voltage VRF is kept constant even when the load current IL changes.

For example, there is a type of circuit that performs feedback control using an operational amplifier (op-amp) as a BGR circuit, but when an operational amplifier is used, noise of the voltage VRF increases. On the other hand, in the Widlar type BGR circuit of FIG. 18, since the feedback control is performed without using the operational amplifier, it is possible to generate the voltage VRF having low noise. In addition, as described above, even when the load current IL changes, the voltage VRF can be kept constant, and a low output impedance can be realized.

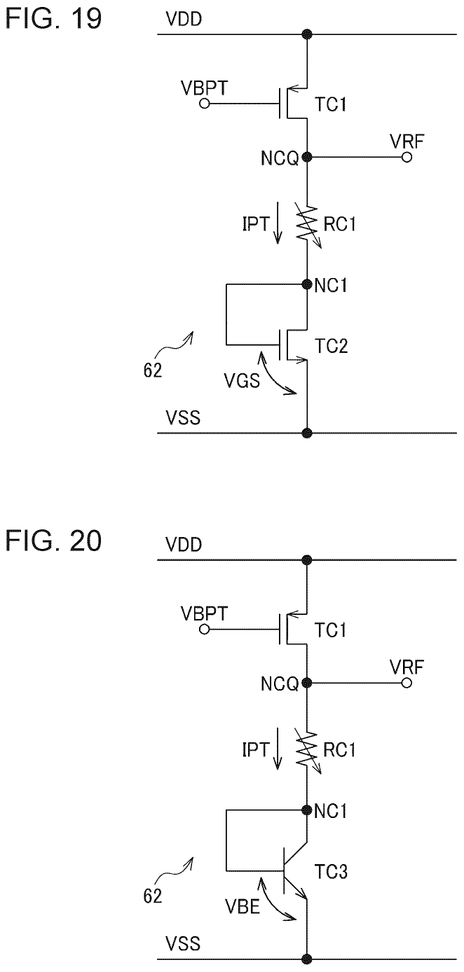

FIG. 19 is another configuration example of the reference circuit 62. FIG. 19 is a PTAT type reference circuit 62. The reference circuit 62 of FIG. 19 includes a transistor TC1, a resistor RC1, and a transistor TC2 that are provided in series between the node of VDD and the node of VSS. The transistor TC1 is a P-type MOS transistor, is provided between the node of VDD and the node NC1, and a bias voltage VBPT for PTAT is input to the gate. The bias voltage VBPT is controlled by the current source of PTAT (not shown), and thus a current IPT of PTAT flows through the resistor RC1. PTAT is an abbreviation for proportional to absolute temperature, and the current of PTAT is a current that increases as the temperature increases. The resistor RC1 is provided between the node of VDD and the node NC1 in series with the transistor TC1 and is a resistor having a variable resistance value. The voltage VRF output from an output node NCQ is adjusted based on a resistance value of the resistor RC1. The transistor TC2 is an N-type MOS transistor, and a gate and a drain are coupled to the node NC1. That is, the N-type transistor TC2 is diode-connected.

In the reference circuit 62 of FIG. 19, when a gate-source voltage of the transistor TC2 is defined as VGS and the resistance value of the resistor RC1 is represented by RC1 having the same reference signs, the voltage of VRF=VGS+RC1. IPT is output from the output node NCQ.

Here, since VGS of the diode-connected transistor TC2 becomes the threshold voltage Vth of the transistor TC2, VGS=Vth has a negative temperature characteristic. In addition, the current IPT of PTAT has a positive temperature characteristic. Therefore, by adjusting a resistance value of the resistor RC1 by VRF=VGS+RC1·IPT, it is possible to generate the voltage VRF having a negative temperature characteristic and generate a reference voltage VRC having a negative temperature characteristic as shown in F1 of FIG. 13. The slope of the first-order temperature characteristic of the reference voltage VRC shown in F1 of FIG. 13 is set to be smaller than the slope of the input lower limit voltage PINMIN shown in F3. The slope setting can also be realized by adjusting the resistance value of the resistor RC1.

In addition, in VRF=VGS+RC1·IPT, by adjusting the resistance value of the resistor RC1, it is also possible to generate a voltage VRF having a positive temperature characteristic to generate a reference voltage VRC having a positive temperature characteristic as shown in J1 of FIG. 16.

FIG. 20 shows still another configuration example of the reference circuit 62. A difference between FIG. 20 and FIG. 19 is that, in FIG. 20, a bipolar transistor TC3 is provided instead of the MOS transistor TC2 of FIG. 19. In the npn bipolar transistor TC3, the base and the collector are coupled to the node NC1, and an emitter is coupled to the node of VSS. Here, when the base-emitter voltage of the bipolar transistor TC3 is defined as VBE, in FIG. 20, the voltage VRF=VBE+RC1·IPT is output from the output node NCQ. Since the voltage VBE has a negative temperature characteristic, as in the case of FIG. 19, by adjusting the resistance value of the resistor RC1, it is possible to generate a voltage VRF having a negative temperature characteristic to generate a reference voltage VRC having a negative temperature characteristic, or to generate a voltage VRF having a positive temperature characteristic to generate a reference voltage VRC having a positive temperature characteristic.

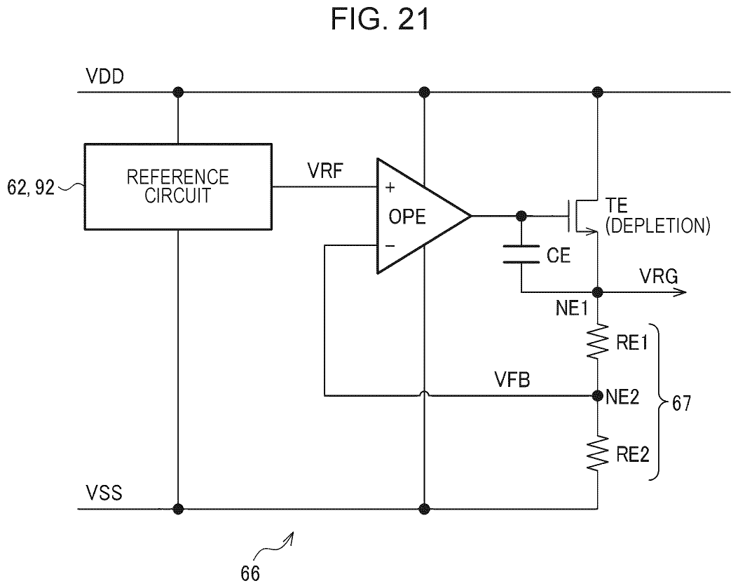

FIG. 21 shows a configuration example of the regulator 66 of FIG. 17. The regulator 66 includes the operational amplifier OPE, a transistor TE, and a voltage division circuit 67.

In the operational amplifier OPE, the voltage VRF is input to the non-inverting input terminal, which is the first input terminal, and a feedback voltage VFB is input to the inverting input terminal, which is the second input terminal. The transistor TE is provided between the node of VDD, which is a first power supply node, and the output node NE1 of the voltage VRG, and the output of the operational amplifier OPE is input to the gate. In FIG. 21, a depletion N-type transistor is used as the transistor TE. However, a P-type transistor may be used as the transistor TE.

The voltage division circuit 67 is provided between the output node NE1 of the voltage VRG and the node of VSS, which is the second power supply node, and generates a voltage obtained by dividing the voltage VRG as the feedback voltage VFB. For example, the voltage division circuit 67 includes resistors RE1 and RE2 provided in series between the output node NE1 and the node of VSS. The feedback voltage VFB from a node NE2 between the resistor RE1 and the resistor RE2 is input to the inverting input terminal of the operational amplifier OPE.

With the regulator 66 of FIG. 21, a voltage of VRG={(RE1+RE2)/RE2}VRF is output. The voltage VRG output by the regulator becomes the reference power supply voltage used in the voltage generation circuit 68 of FIG. 17. The voltage generation circuit 68 generates a reference voltage VRC by voltage-dividing the voltage VRG, which is the reference power supply voltage, by using a resistor circuit or the like.

As described above, as shown in FIGS. 1 and 2, the circuit device 20 of the present embodiment includes the oscillation circuit 30 that causes the resonator 10 to oscillate and generates the oscillation signal, and the temperature compensation circuit 40 that includes the operational amplifier OPD and outputs the temperature compensation voltage VCP of the oscillation frequency of the oscillation signal to the oscillation circuit 30 based on the temperature detection voltage VTS from the temperature detection circuit 50. In addition, the circuit device 20 includes a reference voltage generation circuit 60 for temperature compensation that generates a reference voltage VRC for temperature compensation and outputs the reference voltage VRC to the temperature compensation circuit 40.

Then, the input limit voltage PINLM of the first input terminal of the operational amplifier OPD has the temperature characteristic of the first polarity that is one of positive and negative. In addition, the reference voltage VRC input to the first input terminal of the operational amplifier OPD has the temperature characteristic of the first polarity, which is the same as the polarity of the temperature characteristic of the input limit voltage PINLM. For example, in F3 of FIG. 13, the input lower limit voltage PINMIN, which is the input limit voltage PINLM, has a negative temperature characteristic as the first polarity, and in this case, as shown in F1 of FIG. 13, the reference voltage VRC also has the same negative temperature characteristic. In addition, in J3 of FIG. 16, the input upper limit voltage PINMAX, which is the input limit voltage PINLM, has a positive temperature characteristic as the first polarity, and in this case, as shown in J1 of FIG. 16, the reference voltage VRC also has the same positive temperature characteristic.

In this way, in the present embodiment, the temperature characteristic of the input limit voltage PINLM of the first input terminal of the operational amplifier OPD and the temperature characteristic of the reference voltage VRC are in the same first polarity. Therefore, the input limit voltage PINLM and the reference voltage VRC change with temperature characteristics of the same polarity with respect to temperature changes. Therefore, even when the power supply voltage VDD is lowered, it is possible to suppress the output voltage range of the operational amplifier OPD of the temperature compensation circuit 40 from becoming narrow, and it is possible to realize appropriate temperature compensation.

In the present embodiment, at the temperature of the inflection point of the temperature compensation voltage VCP, the temperature compensation voltage VCP is the reference voltage VRC. For example, in F7 of FIG. 13, the temperature compensation voltage VCP is equal to the reference voltage VRC at a temperature of the inflection point, for example, at a typical temperature. Also in J6 of FIG. 16, the temperature compensation voltage VCP is equal to the reference voltage VRC at a temperature of the inflection point, for example, at a typical temperature.

In this way, by performing temperature compensation of the oscillation frequency using the temperature compensation voltage VCP that becomes the reference voltage VRC at the temperature of inflection point, it becomes possible to generate a temperature-compensated oscillation signal. The reference voltage VRC has the temperature characteristic of the first polarity, and thus, even when the power supply voltage VDD of the circuit device 20 is lowered, it is possible to suppress the voltage range of the temperature compensation voltage VCP from becoming narrow.

In the present embodiment, the temperature compensation circuit 40 outputs the temperature compensation voltage VCP within a voltage range defined by a difference between the output limit voltage of the operational amplifier OPD and the reference voltage VRC. The output limit voltage of the operational amplifier OPD is, for example, the maximum voltage VQMAX=VDL-VOVP of the output voltage VQ of the operational amplifier OPD. Alternatively, the output limit voltage of the operational amplifier OPD is, for example, the minimum voltage VQMIN=VOVN of the output voltage VQ of the operational amplifier OPD. The voltage range of the temperature compensation voltage VCP can be represented, for example, by VRC± (VQMAX−VRC) as shown in the above Equation (5), or can be represented by VRC± (VQMIN-VRC). Therefore, the temperature compensation circuit 40 outputs the temperature compensation voltage VCP in the voltage range defined by VQMAX−VRC and VQMIN−VRC, which are differences between output limit voltages VQMAX and VQMIN and the reference voltage VRC.

In this way, by performing the temperature compensation of the oscillation frequency of the oscillation signal using the temperature compensation voltage VCP in the voltage range defined by the difference between the output limit voltage of the operational amplifier OPD and the reference voltage VRC, it becomes possible to generate the temperature-compensated oscillation signal.

In addition, in the present embodiment, a slope of the first-order temperature characteristic of the reference voltage VRC is smaller than a slope of the first-order temperature characteristic of the input limit voltage. For example, in FIG. 13, the slope of the first-order temperature characteristic of the reference voltage VRC shown in F1 is smaller than the slope of the first-order temperature characteristic of the input lower limit voltage PINMIN shown in F3. In addition, in FIG. 16, the slope of the first-order temperature characteristic of the reference voltage VRC shown in J1 is smaller than the slope of the first-order temperature characteristic of the input upper limit voltage PINMAX shown in J3.

In this way, as in F4 of FIG. 13 or J4 of FIG. 16, the reference voltage VRC is set to be equal to or higher than the input lower limit voltage PINMIN or the reference voltage VRC is set to be equal to or lower than the input upper limit voltage PINMAX at the lower limit temperature of the temperature range. Therefore, appropriate temperature compensation can be realized. That is, it is possible to suppress a voltage range of the temperature compensation voltage VCP from becoming narrow and to realize appropriate temperature compensation.

In addition, in the present embodiment, the operational amplifier OPD includes transistors of a differential pair, and the first polarity is a polarity determined by temperature characteristics of the transistors of the differential pair.

For example, the transistors of the differential pair in the operational amplifier OPD of FIG. 9 are bipolar transistors TB3 and TB4 or N-type MOS transistors. The input lower limit voltage PINMIN of the first input terminal of the operational amplifier OPD is determined by the temperature characteristics of the transistors of the differential pair. In addition, the transistors of the differential pair in the operational amplifier OPD of FIG. 14 are bipolar transistors TG3 and TG4 or P-type MOS transistors. The input upper limit voltage PINMAX of the first input terminal of the operational amplifier OPD is determined by the temperature characteristics of the transistors of the differential pair.

In this way, the first polarity, which is a polarity of the input limit voltage PINLM of the first input terminal of the operational amplifier OPD, is determined by the temperature characteristics of the transistor of the differential pair of the operational amplifier OPD. Then, in the present embodiment, a temperature characteristic of the first polarity that is the same as the polarity of the input limit voltage PINLM determined in this way is provided to the reference voltage VRC.

In addition, in the present embodiment, the transistors of the differential pair are bipolar transistors, and the first polarity is a polarity determined by a temperature characteristic of a base-emitter voltage of the bipolar transistors. For example, the transistors of the differential pair in the operational amplifier OPD of FIG. 9 are the bipolar transistors TB3 and TB4, and the first polarity of the input lower limit voltage PINMIN is determined by VBE, which is the base-emitter voltage of the bipolar transistors TB3 and TB4. In addition, the transistors of the differential pair in the operational amplifier OPD of FIG. 14 are bipolar transistors TG3 and TG4, and the first polarity of the input upper limit voltage PINMAX is determined by VBE, which is the base-emitter voltage of the bipolar transistors TG3 and TG4.

In this way, the first polarity, which is the polarity of the input limit voltage PINLM of the first input terminal of the operational amplifier OPD, is determined by the temperature characteristic of the base-emitter voltage of the bipolar transistors, which are the transistors of the differential pair of the operational amplifier OPD.

In addition, in the present embodiment, the transistors of the differential pair are npn bipolar transistors or N-type MOS transistors, the input limit voltage PINLM of the first input terminal of the operational amplifier OPD is the input lower limit voltage PINMIN, and the first polarity is a negative polarity. For example, the transistors of the differential pair in the operational amplifier OPD of FIG. 9 are npn bipolar transistors TB3 and TB4 or N-type MOS transistors. The input lower limit voltage PINMIN, which is the input limit voltage PINLM of the first input terminal of the operational amplifier OPD, is represented by PINMIN=VBE+VOVN or PINMIN=VGS+VOVN. Since VBE, which is the base-emitter voltage, and VGS, which is the gate-source voltage, have negative temperature characteristics, the first polarity becomes a negative polarity.

In this way, a polarity of the input lower limit voltage PINMIN of the first input terminal of the operational amplifier OPD is determined to be a negative polarity by the temperature characteristics of the base-emitter voltage of the npn bipolar transistor or the gate-source voltage of the N-type MOS transistor, both of which are transistors of the differential pair of the operational amplifier OPD.

In addition, in the present embodiment, in the temperature range of the temperature compensation, the reference voltage VRC is equal to or higher than the input lower limit voltage PINMIN, and the reference voltage VRC at the temperature of the inflection point of the temperature compensation voltage VCP is lower than the input lower limit voltage PINMIN at the lower limit temperature of the temperature range. The temperature range of the temperature compensation corresponds to the usage temperature range of the circuit device 20 and the oscillator 4 as described above. For example, in FIG. 13, the reference voltage VRC shown in F1 is a voltage equal to or higher than the input lower limit voltage PINMIN shown in F3. The reference voltage VRC at the temperature of the inflection point of the temperature compensation voltage VCP shown in F7 of FIG. 13 is lower than the input lower limit voltage PINMIN at the lower limit temperature of the temperature range shown in F4.

In this way, in the temperature range of the temperature compensation, the reference voltage VRC equal to or higher than the input lower limit voltage PINMIN is input to the first input terminal of the operational amplifier OPD, thereby realizing proper operation of operational amplifier OPD. Then, since the reference voltage VRC at the temperature of the inflection point of the temperature compensation voltage VCP becomes lower than the input lower limit voltage PINMIN at the lower limit temperature of the temperature range, it becomes possible to widen a voltage range of the temperature compensation voltage VCP that changes based on the reference voltage VRC.

In addition, in the present embodiment, the transistors of the differential pair are pnp bipolar transistors or P-type MOS transistors, the input limit voltage PINLM of the first input terminal of the operational amplifier OPD is the input upper limit voltage PINMAX, and the first polarity is a positive polarity. For example, the transistors of the differential pair in the operational amplifier OPD of FIG. 14 are the pnp bipolar transistors TG3 and TG4 or the P-type MOS transistors. The input upper limit voltage PINMAX, which is the input limit voltage PINLM of the first input terminal of the operational amplifier OPD, is represented by PINMAX=VDL−VBE−VOVN or PINMAX=VDL−VGS−VOVN. Since VBE, which is the base-emitter voltage, and VGS, which is the gate-source voltage, have negative temperature characteristics, the first polarity becomes a positive polarity.

In this way, a polarity of the input upper limit voltage PINMAX of the first input terminal of the operational amplifier OPD is determined to be a positive polarity by the temperature characteristics of the base-emitter voltage of the pnp bipolar transistor or the gate-source voltage of the P-type MOS transistor, both of which are transistors of the differential pair of the operational amplifier OPD.

In addition, in the present embodiment, in the temperature range of the temperature compensation, the reference voltage VRC is equal to or lower than the input upper limit voltage PINMAX, and the reference voltage VRC at the temperature of the inflection point of the temperature compensation voltage VCP is higher than the input upper limit voltage PINMAX at the lower limit temperature of the temperature range. For example, in FIG. 16, the reference voltage VRC shown in J1 is a voltage equal to or lower than the input upper limit voltage PINMAX shown in J3. The reference voltage VRC at the temperature of the inflection point of the temperature compensation voltage VCP shown in J6 of FIG. 16 is higher than the input upper limit voltage PINMAX at the lower limit temperature of the temperature range shown in J4.

In this way, in the temperature range of the temperature compensation, the reference voltage VRC equal to or lower than the input upper limit voltage PINMAX is input to the first input terminal of the operational amplifier OPD, thereby realizing proper operation of operational amplifier OPD. The reference voltage VRC of the temperature compensation voltage VCP at the temperature of the inflection point of the temperature compensation voltage VCP is higher than the input upper limit voltage PINMAX at the lower limit temperature of the temperature range. Therefore, it is possible to widen the voltage range of the temperature compensation voltage VCP that changes with the reference voltage VRC as a reference.

In addition, as shown in FIG. 3, the temperature compensation circuit 40 includes the current generation circuit 42 and the current-voltage conversion circuit 46. The current generation circuit 42 generates a temperature compensation current ICP based on the temperature detection voltage VTS. The current-voltage conversion circuit 46 includes the operational amplifier OPD1, and generates a temperature compensation voltage VCP by converting the temperature compensation current ICP into a voltage using the operational amplifier OPD1. Then, the reference voltage VRC is input to the first input terminal of the operational amplifier OPD1.

In this way, the current-voltage conversion circuit 46 converts the temperature compensation current ICP generated by the current generation circuit 42 based on the temperature detection voltage VTS into a voltage, so that the temperature compensation voltage VCP is generated, and the temperature compensation of the oscillation frequency of the oscillation signal is performed based on the temperature compensation voltage VCP. Then, the reference voltage VRC having a temperature characteristic of a first polarity that is the same as the polarity of the temperature characteristic of the input limit voltage PINLM is input to the first input terminal of the operational amplifier OPD1 of the current-voltage conversion circuit 46.

### 4. First-Order Correction

In the present embodiment, since the reference voltage VRC has a first-order temperature characteristic as described in F1 of FIGS. 13 and J1 of FIG. 16, there is a possibility that an appropriate temperature compensation voltage VCP cannot be generated. However, as shown in FIG. 3, since the first-order correction circuit 43 of the temperature compensation circuit 40 performs the first-order correction of temperature compensation, it is possible to perform the correction of canceling the first-order temperature characteristics of the reference voltage VRC by using the first-order correction. This point will be described.

For example, in FIG. 3, when the output voltage of the operational amplifier OPD2 is defined as VC1 and the higher-order current from the higher-order correction circuit 44 is defined as ICU, the temperature compensation voltage VCP can be represented as in the following Equation (11).

$$VCP = - \frac{RD}{RD 3} VC 1 - ICU \cdot RD + ( 1 + \frac{RD}{RD 3} ) VRC \qquad ( 11 )$$

When the voltage VC1 and the reference voltage VRC are represented by first-order equations with respect to a temperature (t), they are represented as in the following Equation (12).

$$VC 1 = at + b \qquad ( 12 )$$

$$VRC = ct + d$$

Then, by substituting the above Equation (12) into the above Equation (11), a temperature compensation voltage VCP can be represented as the following Equation (13).

$$VCP = - \frac{RD}{RD 3} ( at + b ) - ICU \cdot RD + ( 1 + \frac{RD}{RD 3} ) ( ct + d ) = ( - \frac{RD}{RD 3} a + ( 1 + \frac{RD}{RD 3} ) c ) t + ( - \frac{RD}{RD 3} b + ( 1 + \frac{RD}{RD 3} ) d ) - ICU \cdot RD \qquad ( 13 )$$

Therefore, even when c in the above Equation (12) is not 0 and the reference voltage VRC has the first-order temperature characteristic represented by ct+d, it can be understood from the above Equation (13) that, in the first-order correction circuit 43, the temperature compensation voltage VCP can be adjusted by first-order gain adjustment for correcting the resistance value of the resistor RD3.

That is, in the present embodiment, the temperature compensation circuit 40 includes the first-order correction circuit 43 as shown in FIG. 3. The first-order correction circuit 43 performs correction for compensating for the first-order temperature characteristic of the temperature compensation voltage due to the temperature characteristic of the reference voltage VRC with reference to the inflection point of the temperature compensation voltage VCP.

As described above, as shown in the above Equation (13), even when the reference voltage VRC has a first-order temperature characteristic, it is possible to perform correction that cancels the first-order temperature characteristic of the reference voltage VRC by using the first-order correction circuit 43 of the temperature compensation circuit 40.

As described above, the circuit device of the present embodiment includes an oscillation circuit configured to cause a resonator to oscillate and generate an oscillation signal, a temperature compensation circuit including an operational amplifier and configured to output a temperature compensation voltage for an oscillation frequency of the oscillation signal to the oscillation circuit based on a temperature detection voltage from a temperature detection circuit, and a reference voltage generation circuit for temperature compensation configured to generate a reference voltage for temperature compensation and output the reference voltage to the temperature compensation circuit. The input limit voltage of the first input terminal of the operational amplifier has the temperature characteristic of the first polarity that is one of positive and negative, and the reference voltage input to the first input terminal of the operational amplifier has the temperature characteristic of the first polarity that is the same as the polarity of the temperature characteristic of the input limit voltage.

According to the present embodiment, the temperature characteristic of the input limit voltage of the first input terminal of the operational amplifier of the temperature compensation circuit and the temperature characteristic of the reference voltage have the same first polarity. Therefore, the input limit voltage and the reference voltage change with the temperature characteristics of the same polarity with respect to temperature changes, and thus, the appropriate temperature compensation can be realized even when the power supply voltage is lowered.

In addition, in the present embodiment, the temperature compensation voltage may be the reference voltage at the temperature of the inflection point of the temperature compensation voltage.

In this way, by performing temperature compensation of the oscillation frequency using the temperature compensation voltage that becomes the reference voltage at the temperature of inflection point, it becomes possible to generate oscillation signal.

In the present embodiment, the temperature compensation circuit may output the temperature compensation voltage within a voltage range defined by a difference between the output limit voltage of the operational amplifier and the reference voltage.

In this way, by performing the temperature compensation of the oscillation frequency of the oscillation signal using the temperature compensation voltage in the voltage range defined by the difference between the output limit voltage of the operational amplifier and the reference voltage, it becomes possible to generate an oscillation signal.

In addition, in the present embodiment, the temperature compensation circuit may include a first-order correction circuit that performs correction for compensating for the first-order temperature characteristic of the temperature compensation voltage due to the temperature characteristic of the reference voltage with reference to the inflection point of the temperature compensation voltage.

In this way, even when the reference voltage has a first-order temperature characteristic, it is possible to perform correction that cancels the first-order temperature characteristic of the reference voltage by using the first-order correction circuit of the temperature compensation circuit.

In addition, in the present embodiment, a slope of the first-order temperature characteristic of the reference voltage may be smaller than a slope of the first-order temperature characteristic of the input limit voltage.

In this way, the reference voltage is set to be equal to or higher than the input lower limit voltage or the reference voltage is set to be equal to or lower than the input upper limit voltage at the lower limit temperature of the temperature range of the temperature compensation. Therefore, appropriate temperature compensation can be realized.

In addition, in the present embodiment, the operational amplifier may include transistors of a differential pair, and the first polarity may be a polarity determined by temperature characteristics of the transistors of the differential pair.

In this way, the first polarity, which is a polarity of the input limit voltage of the first input terminal of the operational amplifier, is determined by the temperature characteristics of the transistor of the differential pair of the operational amplifier.

In addition, in the present embodiment, the transistors of the differential pair may be bipolar transistors, and the first polarity may be a polarity determined by a temperature characteristic of a base-emitter voltage of the bipolar transistors.

In this way, the first polarity, which is the polarity of the input limit voltage of the first input terminal of the operational amplifier, is determined by the temperature characteristic of the base-emitter voltage of the bipolar transistors, which are the transistors of the differential pair of the operational amplifier.

In addition, in the present embodiment, the transistors of the differential pair may be npn bipolar transistors or N-type MOS transistors, the input limit voltage of the first input terminal of the operational amplifier may be the input lower limit voltage, and the first polarity may be a negative polarity.

In this way, a polarity of the input lower limit voltage of the first input terminal is determined to be a negative polarity by the temperature characteristics of the base-emitter voltage of the npn bipolar transistor or the gate-source voltage of the N-type MOS transistor, both of which are transistors of the differential pair of the operational amplifier.

In addition, in the present embodiment, in the temperature range of the temperature compensation, the reference voltage may be equal to or higher than the input lower limit voltage, and the reference voltage at the temperature of the inflection point of the temperature compensation voltage may be lower than the input lower limit voltage at the lower limit temperature of the temperature range.

In this way, when the reference voltage equal to or higher than the input lower limit voltage is input to the first input terminal of the operational amplifier in the temperature range of the temperature compensation, the operational amplifier is properly operated. In addition, because the reference voltage at the temperature of the inflection point is lower than the input lower limit voltage, it is possible to widen the voltage range of the temperature compensation voltage that changes with the reference voltage as a reference.

In addition, in the present embodiment, the transistors of the differential pair may be pnp bipolar transistors or P-type MOS transistors, the input limit voltage of the first input terminal of the operational amplifier may be the input upper limit voltage, and the first polarity may be a positive polarity.

In this way, a polarity of the input upper limit voltage of the first input terminal of the operational amplifier is determined to be a positive polarity by the temperature characteristics of the base-emitter voltage of the pnp bipolar transistor or the gate-source voltage of the P-type MOS transistor, both of which are transistors of the differential pair of the operational amplifier.

In addition, in the present embodiment, in the temperature range of the temperature compensation, the reference voltage may be equal to or lower than the input upper limit voltage, and the reference voltage at the temperature of the inflection point of the temperature compensation voltage may be higher than the input upper limit voltage at the lower limit temperature of the temperature range.

In this way, the reference voltage equal to or lower than the input upper limit voltage is input to the first input terminal of the operational amplifier. Therefore, the operational amplifier is properly operated, and the reference voltage at the temperature of the inflection point is higher than the input upper limit voltage. Therefore, it is possible to widen the voltage range of the temperature compensation voltage that changes with the reference voltage as a reference.

In addition, in the present embodiment, the temperature compensation circuit may include a current generation circuit that generates a temperature compensation current based on a temperature detection voltage, and a current-voltage conversion circuit that includes an operational amplifier and that generates a temperature compensation voltage by converting the temperature compensation current into a voltage using the operational amplifier. The reference voltage may be input to a first input terminal of the operational amplifier.

In this way, by converting the temperature compensation current generated based on the temperature detection voltage into a voltage, the temperature compensation voltage is generated, and the temperature compensation of the oscillation frequency of the oscillation signal is performed based on the temperature compensation voltage. Then, a reference voltage having a temperature characteristic of a first polarity that is the same as the polarity of the temperature characteristic of the input limit voltage is input to the first input terminal of the operational amplifier of the current-voltage conversion circuit.

In addition, the oscillator of the present embodiment includes the circuit device and the resonator described above.

Although the present embodiment is described in detail as described above, those skilled in the art can easily understand that many modifications that do not substantially deviate from new matters and effects of the present disclosure are possible. Therefore, all such modification examples fall within the scope of the present disclosure. For example, a term described at least once together with a different term having a broader meaning or the same meaning in the specification or the drawings can be replaced with a different term anywhere in the specification or drawings. In addition, all combinations of the present embodiment and modification examples also fall within the scope of the present disclosure. In addition, the configuration, operation, and the like of the circuit device and the oscillator are not limited to those described in the present embodiment, and various modifications can be made.

What is claimed is:

1. A circuit device comprising:
an oscillation circuit configured to cause a resonator to oscillate and generate an oscillation signal;
a temperature compensation circuit including an operational amplifier and configured to output a temperature compensation voltage for an oscillation frequency of the oscillation signal to the oscillation circuit based on a temperature detection voltage from a temperature detection circuit; and
a reference voltage generation circuit for temperature compensation configured to generate a reference voltage for temperature compensation and output the reference voltage for temperature compensation to the temperature compensation circuit, wherein
an input limit voltage of a first input terminal of the operational amplifier has a temperature characteristic of a first polarity that is one of positive and negative, and
the reference voltage input to the first input terminal of the operational amplifier has a temperature characteristic of the first polarity that is the same as the polarity of the temperature characteristic of the input limit voltage.

2. The circuit device according to claim 1, wherein
the temperature compensation voltage is the reference voltage at a temperature of an inflection point of the temperature compensation voltage.

3. The circuit device according to claim 1, wherein
the temperature compensation circuit outputs the temperature compensation voltage in a voltage range defined by a difference between an output limit voltage of the operational amplifier and the reference voltage.

4. The circuit device according to claim 1, wherein
the temperature compensation circuit includes a first-order correction circuit that is configured to perform correction for compensating a first-order temperature characteristic of the temperature compensation voltage based on a temperature characteristic of the reference voltage with an inflection point of the temperature compensation voltage as a reference.

5. The circuit device according to claim 1, wherein
a slope of a first-order temperature characteristic of the reference voltage is smaller than a slope of a first-order temperature characteristic of the input limit voltage.

6. The circuit device according to claim 1, wherein
the operational amplifier includes transistors of a differential pair, and
the first polarity is a polarity determined by a temperature characteristic of the transistors of the differential pair.

7. The circuit device according to claim 6, wherein
the transistors of the differential pair are bipolar transistors, and
the first polarity is a polarity determined by a temperature characteristic of a base-emitter voltage of the bipolar transistors.

8. The circuit device according to claim 6, wherein
the transistors of the differential pair are npn bipolar transistors or N-type MOS transistors,
the input limit voltage of the first input terminal of the operational amplifier is an input lower limit voltage, and
the first polarity is a negative polarity.

9. The circuit device according to claim 8, wherein
in a temperature range of temperature compensation, the reference voltage is equal to or higher than the input lower limit voltage, and
the reference voltage at a temperature of an inflection point of the temperature compensation voltage is lower than the input lower limit voltage at a lower limit temperature of the temperature range.

10. The circuit device according to claim 6, wherein
the transistors of the differential pair are pnp bipolar transistors or P-type MOS transistors,
the input limit voltage of the first input terminal of the operational amplifier is an input upper limit voltage, and
the first polarity is a positive polarity.

11. The circuit device according to claim 10, wherein
in a temperature range of temperature compensation, the reference voltage is equal to or lower than the input upper limit voltage, and
the reference voltage at a temperature of an inflection point of the temperature compensation voltage is higher than the input upper limit voltage at a lower limit temperature of the temperature range.

12. The circuit device according to claim 1, wherein
the temperature compensation circuit includes
a current generation circuit configured to generate a temperature compensation current based on the temperature detection voltage, and
a current-voltage conversion circuit including the operational amplifier and configured to generate the temperature compensation voltage by converting the temperature compensation current into a voltage using the operational amplifier, and
the reference voltage is input to the first input terminal of the operational amplifier.

13. An oscillator comprising:
the circuit device according to claim 1; and
the resonator.
